(19) United States
(12) Patent Application Publication
(10) Pub. No.: US 2024/0120893 A1
(43) Pub. Date: Apr. 11, 2024

(54) POWER AMPLIFIER

(71) Applicant: Samsung Electro-Mechanics Co., Ltd., Suwon-si (KR)

(72) Inventors: Jeonghoon KIM, Suwon-si (KR); Jongok HA, Suwon-si (KR); Youngwong JANG, Suwon-si (KR); Shinichi IIZUKA, Suwon-si (KR); Hyejin LEE, Suwon-si (KR)

(73) Assignee: Samsung Electro-Mechanics Co., Ltd., Suwon-si (KR)

(21) Appl. No.: 18/376,644

(22) Filed: Oct. 4, 2023

(30) Foreign Application Priority Data
Oct. 6, 2022 (KR) 10-2022-0128073
Apr. 24, 2023 (KR) 10-2023-0053468

(51) Int. Cl. H03F 3/24; H03F 1/02

(52) U.S. Cl. CPC H03F 3/245; H03F 1/0222; H03F 2200/102; H03F 2200/451

(57) ABSTRACT

A power amplifier includes a power transistor configured to amplify an input radio-frequency (RF) signal, and a bias circuit configured to provide a bias current to the power transistor, and in a first power mode, detect a first signal corresponding to a first level or more in the input RF signal and generate the bias current corresponding to the first signal, or detect a second signal corresponding to a second level or less in the input RF signal and generate the bias current corresponding to the second signal, and in a second power mode, detect a third signal corresponding to a third level or more in the input RF signal and generate the bias current corresponding to the third signal, or detect a fourth signal corresponding to a fourth level or less in the input RF signal and generate the bias current corresponding to the fourth signal.

### CROSS-REFERENCE TO RELATED APPLICATIONS

This application claims the benefit under 35 USC 119(a) of Korean Patent Application Nos. 10-2022-0128073 filed on Oct. 6, 2022, and 10-2023-0053468 filed on Apr. 24, 2023, in the Korean Intellectual Property Office, the entire disclosures of which are incorporated herein by reference for all purposes.

### BACKGROUND

### 1. Field

The following description relates to a power amplifier.

### 2. Description of Related Art

Wireless communication systems apply various digital modulation and demodulation schemes according to the evolution of communication standards. The existing code-division multiple access (CDMA) communication system adopts the quadrature phase-shift keying (QPSK) method, and the existing wireless LAN following the IEEE communication standard adopts the orthogonal frequency-division multiplexing (OFDM) method. In addition, the long-term evolution (LTE) and LTE (Advance (LTE+ or LTE-A) standards, which are recent 3GPP standards, adopt QPSK, quadrature amplitude modulation (QAM), and OFDM schemes. These wireless communication standards implement a linear modulation scheme that necessitates that the intensity or phase of a transmission signal is maintained during transmission.

A power amplifier amplifies the input radio-frequency (RF) signal and transmits it to an antenna. The power amplifier may include a power transistor and a bias circuit providing a bias current to the power transistor. The performance of the power amplifier may be influenced by the direct current sourcing capability (DSC) of the bias circuit. When the DSC is low, a base voltage droop and a gain compression of the power transistor may occur. In addition, when the DSC is high, a gain expansion of the power transistor may occur. That is, the linearity of the power amplifier may deteriorate due to the gain compression or the gain expansion.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a power amplifier includes a power transistor configured to amplify an input radio-frequency (RF) signal; and a bias circuit configured to provide a bias current to the power transistor, wherein the bias circuit is configured to, in a first power mode, detect a first signal corresponding to a first level or more in the input RF signal and generate the bias current as a bias current corresponding to the first signal, or detect a second signal corresponding to a second level or less in the input RF signal and generate the bias current as a bias current corresponding to the second signal, and in a second power mode, detect a third signal corresponding to a third level or more in the input RF signal and generate the bias current as a bias current corresponding to the third signal, or detect a fourth signal corresponding to a fourth level or less in the input RF signal and generate the bias current as a bias current corresponding to the fourth signal.

In the first power mode, the bias current may increase in response to the first signal or the bias current may decrease in response to the second signal, and in the second power mode, the bias current may increase in response to the third signal or the bias current may decrease in response to the fourth signal.

The first signal may correspond to a signal having the first level or more in an upper envelope signal of the input RF signal, the second signal may correspond to a signal having the second level or less in a lower envelope signal of the input RF signal, the third signal may correspond to a signal having the third level or more in the upper envelope signal of the input RF signal, and the fourth signal may correspond to a signal having the fourth level or less in the lower envelope signal of the input RF signal.

The bias circuit may include a main bias circuit configured to generate a main bias current using a reference current; a first signal detection circuit configured to generate the first signal or the third signal using the input RF signal; a second signal detection circuit configured to generate the second signal or the fourth signal using the input RF signal; and an adjustment bias circuit configured to generate an adjustment bias current corresponding to the first signal, or the second signal, or the third signal, or the fourth signal, and the bias current may be equal to a sum of the main bias current and the adjustment bias current.

The main bias circuit may include a first transistor configured to provide the main bias current to the power transistor, and the adjustment bias circuit may include a second transistor configured to provide the adjustment bias current to the power transistor.

The first transistor may include a control terminal to which a current corresponding to the reference current is input, and a first terminal from which the main bias current is output, the second transistor may include a control terminal to which the first signal, or the second signal, or the third signal, or the fourth signal is input, and a first terminal from which the adjustment bias current is output, the first terminal of the first transistor and the first terminal of the second transistor may be connected to each other, and the adjustment bias circuit may further include a first resistor connected between the control terminal of the first transistor and the control terminal of the second transistor.

The first power mode may be any one of a high power mode, a medium power mode, and a low power mode, and the second power mode may be any one of the high power mode, the medium power mode, and the low power mode that is not the first power mode.

The bias circuit may further include a switch configured to select any one of the first to fourth signals according to the first and second power modes and output the selected any one signal to the adjustment bias circuit.

The first signal detection circuit may be further configured to, in the first power mode, generate the first signal as a first signal corresponding to a signal having the first level or more in an upper envelope signal of the input RF signal, and in the second power mode, generate the third signal as a third signal corresponding to a signal having the third level or more in an upper envelope signal of the input RF signal.

The second signal detection circuit may be further configured to, in the first power mode, generate the second signal as a second signal corresponding to a signal having the second level or less in a lower envelope signal of the input RF signal, and in the second power mode, generate the fourth signal as a fourth signal corresponding to a signal having the fourth level or less in a lower envelope signal of the input RF signal.

The first level may be the same as the third level, and the second level may be the same as the fourth level.

In another general aspect, a power amplifier includes a power transistor configured to amplify an input radio-frequency (RF) signal; and a bias circuit configured to provide a bias current to the power transistor, wherein the bias circuit is further configured to detect a first signal corresponding to a first level or more in the input RF signal and generate the bias current as a bias current corresponding to the first signal.

The first signal may be a signal corresponding to the first level or more in a upper envelope signal of the input RF signal.

The bias current may increase in response to the first signal.

The bias circuit may include a main bias circuit configured to generate a main bias current using a reference current; a signal detection circuit configured to detect the first signal using the input RF signal; and an adjustment bias circuit configured to generate an adjustment bias current corresponding to the first signal, wherein the bias current may be equal to a sum of the main bias current and the adjustment bias current.

The main bias circuit may include a first transistor configured to provide the main bias current to the power transistor, and the adjustment bias circuit may include a second transistor configured to provide the adjustment bias current to the power transistor.

The first transistor may include a control terminal to which a current corresponding to the reference current is input, and a first terminal from which the main bias current is output, the second transistor may include a control terminal to which the first signal is input, and a first terminal from which the adjustment bias current is output, the first terminal of the first transistor and the first terminal of the second transistor may be connected to each other, and the adjustment bias circuit may further include a first resistor connected between the control terminal of the first transistor and the control terminal of the second transistor.

The signal detection circuit may include a first terminal to which the input RF signal is input; a diode having an anode connected to the first terminal; a bias voltage generating circuit configured to provide a bias voltage to the anode of the diode; a capacitor connected between a cathode of the diode and a ground; and a second terminal configured to output the first signal.

The bias voltage generating circuit may be further configured to generate the bias voltage as a bias voltage having a value that varies according to a power mode.

The signal detection circuit may further include a first resistor connected between the bias voltage generating circuit and the anode of the diode; a variable resistor having one end connected to the cathode of the diode and a resistance that varies according to the power mode; and a second resistor connected between another end of the variable resistor and the ground.

The variable resistor may have a first resistance in a first power mode and a second resistance lower than the first resistance in a second power mode, and the first power mode may be a power mode requiring a higher power than the second power mode.

The bias voltage generating circuit may include a transistor including a control terminal, a first terminal, and a second terminal, wherein the first terminal is configured to be connected to a power supply voltage; a first resistor having one end connected to the second terminal of the transistor; a second resistor connected between another end of the first resistor and the ground; and a switch configured to output the bias voltage by selecting a voltage at the second terminal of the transistor or a voltage at another end of the first resistor according to the power mode.

The bias voltage may have a first voltage value in a first power mode and a second voltage value higher than the first voltage value in a second power mode, and the first power mode may be a power mode requiring a higher power than the second power mode.

The signal detection circuit may further include a first resistor connected between the bias voltage generating circuit and the anode of the diode; a variable gain amplifier having an input terminal connected to the cathode of the diode and having a gain that varies according to the power mode; and a second resistor connected between an output terminal of the variable gain amplifier and the ground.

The gain may have a first gain value in a first power mode and a second gain higher than the first gain in a second power mode, and the first power mode may be a power mode requiring a higher power than the second power mode.

In another general aspect, a power amplifier includes a power transistor configured to amplify an input radio-frequency (RF) signal; and a bias circuit configured to provide a bias current to the power transistor, wherein the bias circuit is further configured to detect a first signal corresponding to a first level or less in the input RF signal and generate the bias current as a bias current corresponding to the first signal.

The first signal may be a signal corresponding to the first level or less in a lower envelope signal of the input RF signal.

The bias current may decrease in response to the first signal.

The bias circuit may include a main bias circuit configured to generate a main bias current using a reference current; a signal detection circuit configured to detect the first signal using the input RF signal; and an adjustment bias circuit configured to generate an adjustment bias current corresponding to the first signal, wherein the bias current may equal to a sum of the main bias current and the adjustment bias current.

The signal detection circuit may include a first terminal to which the input RF signal is input; a diode having a cathode connected to the first terminal; a bias voltage generating circuit configured to provide a bias voltage to an anode of the diode; a capacitor connected between the anode of the diode and a ground; and a second terminal configured to output the first signal.

The bias voltage generating circuit may be further configured to generate the bias voltage as a bias voltage having a value that varies according to a power mode.

The signal detection circuit may further include a first resistor connected between the cathode of the diode and the ground; a variable resistor having one end connected to the anode of the diode and having a resistance that varies according to the power mode; and a second resistor connected between the bias voltage generating circuit and another end of the variable resistor.

The variable resistor may have a first resistance in a first power mode and a second resistance lower than the first resistance in a second power mode, and the first power mode may be a power mode requiring a higher power than the second power mode.

The signal detection circuit may further include a first resistor connected between the cathode of the diode and the ground; a variable gain amplifier having an input terminal connected to the anode of the diode and having a gain that varies according to the power mode; and a second resistor connected between the bias voltage generating circuit and an output terminal of the variable gain amplifier.

The gain may be a first gain in a first power mode and a second gain higher than the first gain in a second power mode, and the first power mode may be a power mode requiring a higher power than the second power mode.

The bias voltage may have a first voltage value in a first power mode and a second voltage value higher than the first voltage value in a second power mode, and the first power mode may be a power mode requiring a higher power than the second power mode.

In another general aspect, a power amplifier includes a first power transistor configured to amplify a first input radio-frequency (RF) signal; a first bias circuit configured to provide a first bias current to the first power transistor; a second power transistor configured to amplify a second input RF signal; and a second bias circuit configured to provide a second bias current to the second power transistor, wherein the first bias circuit is further configured to detect a first signal corresponding to a first level or more in the first input RF signal and generate the first bias current as a first bias current corresponding to the first signal, and the second bias circuit is further configured to detect a second signal corresponding to a second level or less in the second input RF signal and generate the second bias current as a second bias current corresponding to the second signal.

The second input RF signal may be an RF signal amplified and output by the first power transistor.

The first bias current may increase in response to the first signal, and the second bias current may decrease in response to the second signal.

The first signal may be a first signal corresponding to the first level or more in a upper envelope signal of the first input RF signal, and the second signal may be a second signal corresponding to the second level or less in a lower envelope signal of the second input RF signal.

The first bias circuit may include a first main bias circuit configured to generate a first main bias current using a first reference current; a first signal detection circuit configured to generate the first signal using the first input RF signal; and a first adjustment bias circuit configured to generate a first adjustment bias current corresponding to the first signal, and the second bias circuit may include a second main bias circuit configured to generate a second main bias current using the second reference current; a second signal detection circuit configured to generate the second signal using the second input RF signal; and a second adjustment bias circuit configured to generate a second adjustment bias current corresponding to the second signal, wherein the first bias current may be equal to a sum of the first main bias current and the first adjustment bias current, and the second bias current may be equal to a sum of the second main bias current and the second adjustment bias current.

The first main bias circuit may include a first transistor configured to provide the first main bias current to the first power transistor, the first adjustment bias circuit may include a second transistor configured to provide the first adjustment bias current to the first power transistor, the second main bias circuit may include a third transistor configured to provide the second main bias current to the second power transistor, and the second adjustment bias circuit may include a fourth transistor configured to provide the second adjustment bias current to the second power transistor.

The first signal detection circuit may be further configured to generate the first signal as a first signal corresponding to a signal having the first level or more in an upper envelope signal of the first input RF signal, and the second signal detection circuit may be further configured to generate the second signal as a second signal corresponding to a signal having the second level or less in a lower envelope signal of the second input RF signal.

The first power transistor and the first bias circuit may constitute a first stage amplifier, and the second power transistor and the second bias circuit may constitute a second stage amplifier.

Other features and aspects will be apparent from the following detailed description, the drawings, and the claims.

### BRIEF DESCRIPTION OF DRAWINGS

FIG. 1A is a graph showing a gain compression that occurs in a general power amplifier.

FIG. 1B is a graph showing a gain expansion that occurs in a general power amplifier.

FIG. 2 illustrates a power amplifier 1000A according to an example.

FIG. 3 is a diagram showing internal configurations of the main bias circuit 210 and the adjustment bias circuit 220A of FIG. 2.

FIG. 4A is a diagram illustrating the signal detection circuit 230A of FIG. 2 according to an example.

FIG. 4B is a diagram illustrating a signal detection circuit 230A′ according to another example.

FIG. 5 is a diagram illustrating the bias voltage generating circuit 231 of FIGS. 4A and 4B according to an example.

FIG. 6 is a graph showing a current (I)-voltage (V) characteristic of the diode D1 of FIGS. 4A and 4B when using the bias voltage generating circuit 231 of FIG. 5.

FIG. 7 is a diagram illustrating a bias voltage generating circuit 231′ according to another example.

FIG. 8 is a graph showing a current (I)-voltage (V) characteristic of the diode D1 of FIGS. 4A and 4B when using the bias voltage generating circuit 231′ of FIG. 7.

FIG. 9 is a diagram showing an example of signals in the signal detection circuits 230 and 230A′ of FIGS. 4A and 4B.

FIG. 10A is a graph conceptually illustrating the main bias current I_{MAIN_A}.

FIG. 10B is a graph conceptually illustrating the adjustment bias current I_{ADJ_A}.

FIG. 10C is a graph conceptually illustrating the bias current I_{BIAS_A}.

FIG. 11 is a graph showing a linearity improvement of the power amplifier 1000A according to an example.

FIG. 12 illustrates a power amplifier 1000B according to another example.

FIG. 13 is a diagram showing internal configurations of the main bias circuit 210 and the adjustment bias circuit 220B of FIG. 12.

FIG. 14A is a diagram illustrating a signal detection circuit 230B according to an example.

FIG. 14B is a diagram illustrating a signal detection circuit 230B′ according to another example.

FIG. 15 is a diagram showing an example of signals in the signal detection circuits 230B and 230B′ of FIGS. 14A and 14B.

FIG. 16A is a graph conceptually illustrating the main bias current I_{MAIN_A}.

FIG. 16B is a graph conceptually illustrating the adjustment bias current I_{ADJ_B}.

FIG. 16C is a graph conceptually illustrating the bias current I_{BIAS_B}.

FIG. 17 is a graph showing a linearity improvement of the power amplifier 1000B according to another example.

FIG. 18 is a diagram illustrating a power amplifier 1000C according to another example.

FIG. 19 is a diagram showing internal configurations of the main bias circuit 210 and the adjustment bias circuit 220C of FIG. 18.

FIG. 20 is a diagram illustrating a power amplifier 2000 according to another example.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The use of the term “may” with respect to an example or embodiment, e.g., as to what an example or embodiment may include or implement, means that at least one example or embodiment exists in which such a feature is included or implemented, while all examples and embodiments are not necessarily limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

In this application, an RF signal includes Wi-Fi (IEEE 802.11 family, etc.), WiMAX (IEEE 802.16 family, etc.), IEEE 802.20, LTE (long-term evolution), (EV-DO), HSPA+, HSDPA+, HSUPA+, EDGE, GSM, GPS, GPRS, CDMA, TDMA, DECT, Bluetooth, 3G, 4G, 5G, and any other wireless and wired protocols designated hereafter, but is not limited thereto.

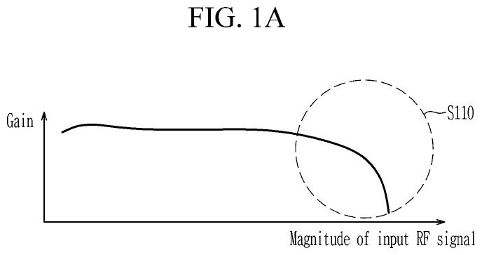

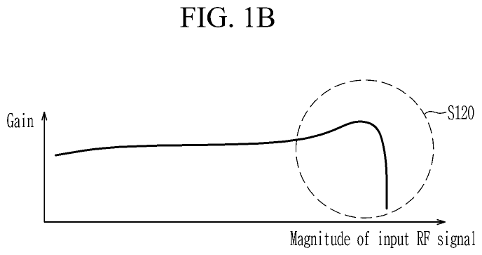

FIG. 1A is a graph showing a gain compression that occurs in a general power amplifier.

In FIG. 1A, the horizontal axis represents the magnitude of the input RF signal input to the power amplifier, and the vertical axis represents the gain of the power amplifier. As described in the Background section, when the DSC of the bias circuit is low, a gain compression may occur. The gain decreases as the magnitude of the input RF signal increases. The gain initially decreases gradually, and then decreases more sharply near the output saturation power of the power amplifier. Particularly, referring to S110 of FIG. 1A, the gain may decrease more sharply as the magnitude of the input RF signal increases near the output saturation power. The magnitude of the input RF signal may indicate an absolute value of the level of the input RF signal.

FIG. 1B is a graph showing a gain expansion that occurs in a general power amplifier.

In FIG. 1B, the horizontal axis represents the magnitude of the input RF signal input to the power amplifier, and the vertical axis represents the gain of the power amplifier. As described in the Background section, when the DSC of the bias circuit is high, a gain expansion may occur. The gain increases as the magnitude of the input RF signal increases. The gain initially increases gradually, and then increases more sharply near the output saturation power of the power amplifier. Particularly, referring to S120 of FIG. 1B, the gain may increase more sharply as the magnitude of the input RF signal increases near the output saturation power.

Examples of improving the gain compression shown in FIG. 1A or the gain expression shown in FIG. 1B are described below. Examples described below may improve linearity by controlling the bias current in response to the level of the input RF signal. As one example, when the power amplifier has a gain compression characteristic, the power amplifier may generate a bias current by detecting a signal having a predetermined level or more in the input RF signal. As another example, when the power amplifier has a gain expansion characteristic, the power amplifier may generate a bias current by detecting a signal having a predetermined level or less in the input RF signal.

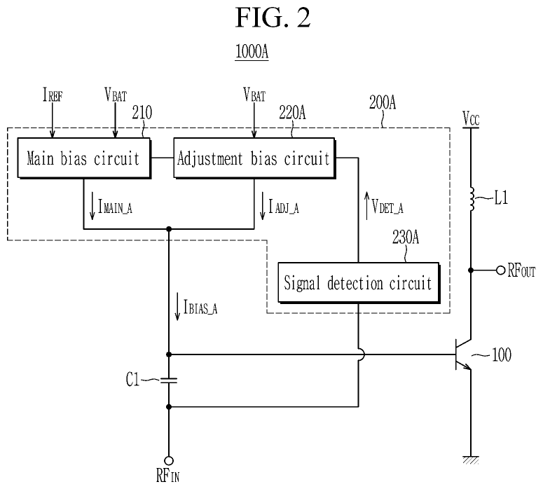

FIG. 2 illustrates a power amplifier 1000A according to an example.

As shown in FIG. 2, the power amplifier 1000A may include a power transistor 100, a bias circuit 200A, a capacitor C1, and an inductor L1.

In FIG. 2, an input RF signal input to the power amplifier 1000A is denoted by ‘RF_{IN}’, and an output RF signal output from the power amplifier 1000A is denoted by ‘RF_{OUT}’.

The power transistor 100 may include an input terminal and an output terminal. The input terminal may be the base of the power transistor 100, and the output terminal may be the collector of the power transistor. The power transistor 100 may amplify a power of the input RF RF_{IN} input to the input terminal (for example, the base) and output the amplified power to the output terminal (for example, the collector). An emitter of the power transistor 100 may be connected to a ground, and although not shown in FIG. 2, a resistor may be connected between the emitter of the power transistor 100 and the ground. In addition, the collector of the power transistor 100 may be connected to a power supply voltage V_{CC} through the inductor L1, and the power transistor 100 may be operated by the power supply voltage V_{CC}. The inductor L1 may be connected between the power supply voltage V_{CC} and the collector of the power transistor 100 and may perform an RF choke function.

The power transistor 100 may be implemented by various types of transistors such as a heterojunction bipolar transistor (HBT), a bipolar junction transistor (BJT), and an insulated gate bipolar transistor (IGBT). In addition, although the power transistor 100 is shown as an n-type transistor in FIG. 2, it may be replaced with a p-type transistor.

The capacitor C1 is a coupling capacitor and may be connected to the input terminal (for example, the base) of the power transistor 100. That is, the input RF signal RF_{IN} may be input to one end of the capacitor C1, and the other end of the capacitor C1 may be connected to the base of the power transistor 100. The capacitor C1 may perform a function of blocking a direct current (DC) component in the input RF signal RF_{IN}.

The bias circuit 200A may receive a reference current I_{REF} and a power supply voltage V_{BAT} from the outside. The power supply voltage V_{BAT} may be a voltage supplied from a battery. The bias circuit 200A may generate a bias current I_{BIAS_A} required by the power transistor 100 using the reference current I_{REF} and the power supply voltage V_{BAT}. The bias current I_{BIAS_A} is supplied to the input terminal (for example, the base) of the power transistor 100, and a bias level (a bias point) of the power transistor 100 may be set by the bias current I_{BIAS_A}.

A power amplifier may be designed in advance to have a gain compression characteristic as shown in FIG. 1A according to a purpose or design direction. In order to improve the linearity of a power amplifier having a gain compression characteristic, the power amplifier 1000A may detect a signal having a predetermined level or more in the input RF signal RF_{IN}, and generate the bias current I_{BIAS_A} corresponding to the detected signal.

As shown in FIG. 2, the bias circuit 200A may include a main bias circuit 210, an adjustment bias circuit 220A, and a signal detection circuit 230A.

The main bias circuit 210 may receive the reference current I_{REF} and the power supply voltage V_{BAT} from the outside. The main bias circuit 210 may generate a main bias current I_{MAIN_A} using the reference current I_{REF} and the power supply voltage V_{BAT}.

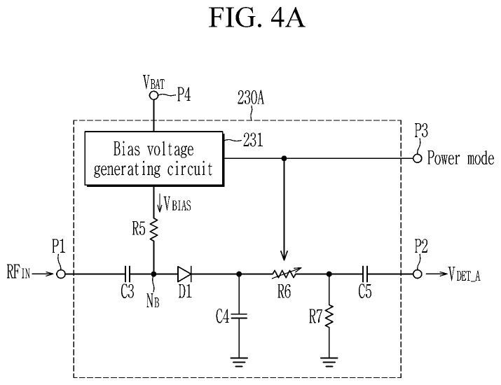

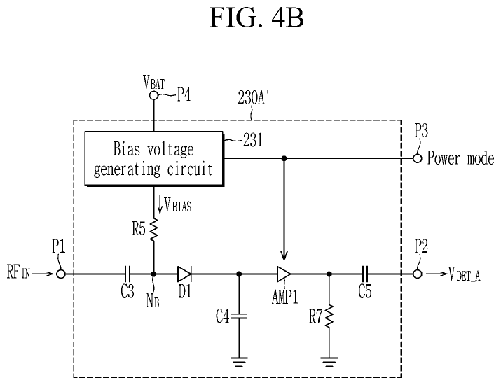

The signal detection circuit 230A may receive the input RF signal RF_{IN} and generate a detection signal V_{DET_A} corresponding to a signal having a predetermined level or more in the input RF signal RF_{IN}. The detection signal V_{DET_A} is input to the adjustment bias circuit 220A. The detection signal V_{DET_A} may be a voltage signal. In more detail, the signal detection circuit 230A may generate the detection signal V_{DET_A}, which is a signal corresponding to a predetermined level or more in an upper envelope signal of the input RF signal RF_{IN}. That is, the signal detection circuit 230A may generate the detection signal V_{DET_A} using an upper envelope signal of the input RF signal RF_{IN}. Examples of the signal detection circuit 230A will be described with reference to FIGS. 4A and 4B below. The upper envelope signal of the input RF signal RF_{IN} may mean an envelope for an RF signal having a higher level than the average signal level of the input RF signal RF_{IN}. For example, when the average signal level of the input RF signal RF_{IN} is 0 V, the upper envelope signal may mean an envelope for an RF signal higher than 0 V in the input RF signal RF_{IN}.

The adjustment bias circuit 220A may receive the power supply voltage V_{BAT} from the outside and may receive the detection signal V_{DET_A} from the signal detection circuit 230A. The adjustment bias circuit 220A may generate an adjustment bias current I_{ADJ_A} using the power supply voltage V_{BAT} and the detection signal V_{DET_A}. The adjustment bias current I_{ADJ_A} may vary in response to the detection signal V_{DET_A}. Since the detection signal V_{DET_A} corresponds to the input RF signal RF_{IN}, the adjustment bias current I_{ADJ_A} may vary in response to the input RF signal RF_{IN}.

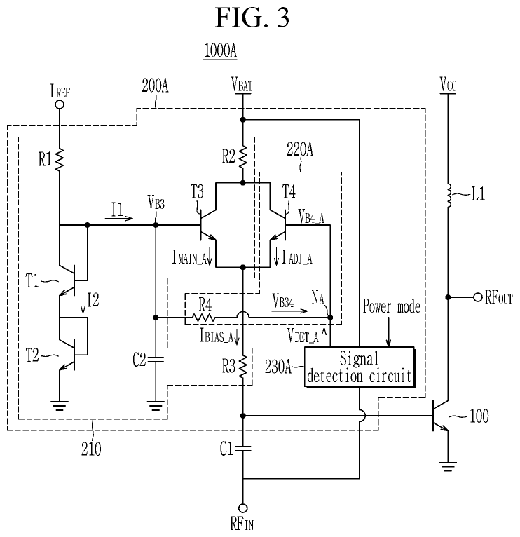

The adjustment bias circuit 220A and the main bias circuit 210 are connected to each other, which will be described in more detail in FIG. 3 below.

The main bias current I_{MAIN_A} generated by the main bias circuit 210 and the adjustment bias current I_{ADJ_A} generated by the adjustment bias circuit 220A are added together and provided to the input terminal (base) of the power transistor 100. That is, the bias current I_{BIAS_A}, the main bias current I_{MAIN_A}, and the adjustment bias current I_{ADJ_A} may have a relationship expressed by Equation 1 below.

I_{BIAS_A}=I_{MAIN_A}+I_{ADJ_A} (1)

Assuming that the main bias current I_{MAIN_A} has a fixed value, the bias current I_{BIAS_A} may vary according to the adjustment bias current I_{ADJ_A}. As described above, since the adjustment bias current I_{ADJ_A} varies in response to the input RF signal RF_{IN}, the bias current I_{BIAS_A} may vary in response to the input RF signal RF_{IN}. When the input RF signal RF_{IN} has a value equal to or greater than a predetermined level, the adjustment bias current I_{ADJ_A} may increase. By increasing the adjustment bias current I_{ADJ_A}, a gain compression as shown in FIG. 1A may be improved. Improvement of the gain compression may mean that a linearity of the power amplifier 1000A is improved.

FIG. 3 is a diagram showing internal configurations of the main bias circuit 210 and the adjustment bias circuit 220A of FIG. 2.

As shown in FIG. 3, the main bias circuit 210 may include a transistor T1, a transistor T2, a transistor T3, a resistor R1, a resistor R2, a resistor R3, and a capacitor C2.

The transistors T1 to T3 may be implemented by various types of transistors such as a heterojunction bipolar transistor (HBT), a bipolar junction transistor (BJT), and an insulated gate bipolar transistor (IGBT). In addition, although the transistors T1 to T3 are shown as n-type transistors in FIG. 3, they may be replaced with p-type transistors.

Since the bases of the transistors T1 to T3 serve as control terminals, the term ‘control terminal’ may be used. Since the collectors of the transistors T1 to T3 are one terminal of the transistor, the terms ‘first terminal’ or ‘second terminal’ may be used. In addition, since the emitters of the transistors T1 to T3 are also one terminal of the transistor, the terms ‘second terminal’ or ‘first terminal’ may be used.

A base and a collector of the transistor T1 may be connected to each other in a diode connection structure, and a collector of the transistor T1 may receive the reference current I_{REF} through the resistor R1. Transistor T1 serves to sink a current I2 from the reference current I_{REF}. The reference current I_{REF} may be a current source.

A base and a collector of the transistor T2 may be connected to each other in a diode connection structure, and the collector of the transistor T2 may be connected to the emitter of the transistor T1. An emitter of the transistor T2 may be connected to a ground. Although not shown in FIG. 3, a resistor may be connected between the emitter of the transistor T2 and the ground.

A collector of the transistor T3 may be connected to the power supply voltage V_{BAT} through the resistor R2, and a base of the transistor T3 may be connected to the base of the transistor T1. In FIG. 3, a base voltage of the transistor T3 is denoted by ‘V_{B3}’. In addition, an emitter of the transistor T3 may be connected to the input terminal (for example, the base) of the power transistor 100 through the resistor R3. A current flowing through the emitter of the transistor T3 is the main bias current I_{MAIN_A} described in FIG. 2. That is, the emitter of the transistor T3 may provide the main bias current I_{MAIN_A}.

The capacitor C2 may be connected between the base of transistor T3 and the ground. The capacitor C2 may stabilize the base voltage V_{B3} of the transistor T3 and reduce an impedance of the transistor T3.

The reference current I_{REF} is divided into a current I1 and the current I2, and the current I1 may be input to the base of the transistor T3. Accordingly, the main bias current I_{MAIN_A} may be determined corresponding to the current I1. Also, the main bias current I_{MAIN_A} may be determined corresponding to the base voltage V_{B3} of the transistor T3.

As shown in FIG. 3, the adjustment bias circuit 220A may include a transistor T4 and a resistor R4.

The transistor T4 may be implemented by various types of transistors such as a heterojunction bipolar transistor (HBT), a bipolar junction transistor (BJT), and an insulated gate bipolar transistor (IGBT). In addition, although the transistor T4 is shown as an n-type transistor in FIG. 3, it may be replaced with a p-type transistor.

Since a base of the transistor T4 serves as a control terminal, the term ‘control terminal’ may be used. Since a collector of the transistor T4 is one terminal of the transistor, the terms ‘first terminal’ or ‘second terminal’ may be used. Also, since an emitter of the transistor T4 is also one terminal of the transistor, the terms ‘second terminal’ or ‘first terminal’ may be used.

A collector of the transistor T4 may be connected to the power supply voltage V_{BAT} through the resistor R2, and a base of the transistor T4 may be connected to the base of transistor T3 through the resistor R4. Also, the base of the transistor T4 is connected to the signal detection circuit 230A to receive the detection signal V_{DET_A}. In FIG. 3, the base voltage of the transistor T4 is denoted by ‘V_{B4_A}’, and the node where the base of the transistor T4, the signal detection circuit 230A, and the resistor R4 are connected to each other is denoted by ‘N_{A}’.

The resistor R4 may be connected between the base of the transistor T3 and the base of the transistor T4. When the value of the resistor R4 is set to a high value, the base voltage V_{B3} of the transistor T3 may affect the base voltage V_{B4_A} of the transistor T4 from a direct current (DC) point of view. A voltage due to this affection is denoted by ‘V_{B34}’ in FIG. 3. In addition, when the value of the resistor R4 is set to a high value, the base voltage V_{B3} of the transistor T3 and the base voltage V_{B4_A} of the transistor T4 may not affect each other from the viewpoint of alternating current (AC). Accordingly, from the viewpoint of an AC signal (i.e., an RF signal), the detection signal V_{DET_A} may not affect the base voltage V_{B3} of the transistor T3. Because of the resistor R4, a separate power supply biasing the base of the transistor T4 may not be required.

The base voltage V_{B4_A} of the transistor T4 may be equal to a sum of the voltage V_{B34} and the detection signal V_{DET_A}. That is, the base voltage V_{B4_A} of the transistor T4, the voltage V_{B34}, and the detection signal V_{DET_A} may have a relationship expressed by Equation 2 below.

V_{B4_A}=V_{B34}+V_{DET_A} (2)

The detection signal V_{DET_A} may be an RF signal (i.e., an AC signal), and the voltage V_{B34} may be a DC signal.

The emitter of the transistor T4 may be connected to the input terminal (i.e., base) of the power transistor 100 through the resistor R3. That is, the emitter of the transistor T3 and the emitter of the transistor T4 may be connected to each other. One end of the resistor R3 may be connected to the emitter of the transistor T3 and the emitter of the transistor T4, and the other end of the resistor R3 may be connected to the base of the power transistor 100. A current flowing through the emitter of the transistor T4 is the adjustment bias current I_{ADJ_A} described in FIG. 2. That is, the emitter of the transistor T4 may provide the adjustment bias current I_{ADJ_A}.

The adjustment bias current I_{ADJ_A} may vary in response to the base voltage V_{B4_A} of the transistor T4. In Equation 2, assuming that the voltage V_{B34} is a fixed value, the base voltage V_{B4_A} of the transistor T4 may vary in response to the detection signal V_{DET_A}. Accordingly, the adjustment bias current I_{ADJ_A} may vary in response to the detection signal V_{DET_A}. When the base voltage V_{B3} of the transistor T3 is a fixed value, the main bias current I_{MAIN_A} may be a fixed value and the voltage V_{B34} may also be a fixed value. Accordingly, when Equations 1 and 2 are considered together, the bias current I_{BIAS_A} may vary in response to the detection signal V_{DET_A}.

FIG. 4A is a diagram illustrating the signal detection circuit 230A of FIG. 2 according to an example.

As shown in FIG. 4A, the signal detection circuit 230A according to an example may include a plurality of terminals P1, P2, P3, and P4, a capacitor C3, a bias voltage generating circuit 231, a resistor R5, a diode D1, a capacitor C4, a variable resistor R6, a resistor R7, and a capacitor C5.

The input RF signal RF_{IN} is input to the terminal P1, and the detection signal V_{DET_A} is output from the terminal P2. That is, the terminal P1 may be connected to one end of the capacitor C1, and the terminal P2 may be connected to the base (i.e., node N_{A}) of the transistor T4. In addition, the power supply voltage V_{BAT} may be input to the terminal P4.

A power mode is input to the terminal P3. As an example, the power mode may include a high power mode (HPM) and a low power mode (LPM). As another example, the power mode may include a high power mode (HPM), a medium power mode (MPM), and a low power mode (LPM).

One end of the capacitor C3 may be connected to the terminal P1. The capacitor C3 is a coupling capacitor, and may perform a function of blocking a direct current (DC) component of the input RF signal RF_{IN}.

An anode of the diode D1 may be connected to the other end of the capacitor C3. In FIG. 4A, a node where the diode D1 and the capacitor C3 are connected to each other is denoted by ‘N_{B}’. The capacitor C4 may be connected between a cathode of the diode D1 and a ground.

One end of the variable resistor R6 may be connected to the cathode of the diode D1, and the resistor R7 may be connected between the other end of the variable resistor R6 and the ground. A resistance of the variable resistor R6 may vary according to the power mode. In order to set the magnitude of the detection signal V_{DET_A} to a similar magnitude regardless of the power mode, the variable resistor R6 may have different resistances in different power modes. That is, a signal attenuation may be set differently according to the power mode by the resistance of the variable resistor R6 that varies according to the power mode. Since the magnitude of the input RF signal RF_{IN} is large in the high power mode, the variable resistor R6 may have a large resistance in the high power mode. Also, since the magnitude of the input RF signal RF_{IN} is small in the low power mode, the variable resistor R6 may have a small resistance in the low power mode. That is, the resistance of the variable resistor R6 may be set to a larger resistance in the high power mode than in the low power mode.

The capacitor C5 may be connected between the other end of the variable resistor R6 and the terminal P2. The capacitor C5 is a coupling capacitor, and may perform a function of blocking a direct current (DC) component the detection signal V_{DET_A}.

The bias voltage generating circuit 231 may generate a bias voltage V_{BIAS} using the power supply voltage V_{BAT} input through the terminal P4. The bias voltage generation circuit 231 may generate the bias voltage V_{BIAS} having a different value according to the power mode input through the terminal P3. The resistor R5 is connected between the bias voltage generating circuit 231 and the node N_{B}, and the bias voltage V_{BIAS} may be applied to the anode of the diode D1 through the resistor R5. By means of the bias voltage V_{BIAS}, an operating voltage of the diode D1 may be set differently according to the power mode.

FIG. 4B is a diagram illustrating a signal detection circuit 230A′ according to another example.

As shown in FIG. 4B, the signal detection circuit 230A′ according to another example may include a plurality of terminals P1, P2, P3, and P4, a capacitor C3, a bias voltage generating circuit 231, and a resistor R5, a diode D1, a capacitor C4, a variable gain amplifier AMP1, a resistor R7, and a capacitor C5. The signal detection circuit 230A′ of FIG. 4B is the same as the signal detection circuit 230A of FIG. 4A except that the variable resistor R6 is replaced with the variable gain amplifier AMP1. Accordingly, overlapping descriptions may be omitted.

An input terminal of the variable gain amplifier AMP1 may be connected to the cathode of the diode D1, and an output terminal of the variable gain amplifier AMP1 may be connected to one end of the resistor R7. The resistor R7 may be connected between the output terminal of the variable gain amplifier AMP1 and the ground.

The gain of the variable gain amplifier AMP1 may vary according to the power mode. In order to set the magnitude of the detection signal V_{DET_A} to a similar magnitude regardless of the power mode, the variable gain amplifier AMP1 may have a different gains in different power modes. That is, the degree of signal amplification may be set differently according to the power mode by the gain of the variable gain amplifier AMP1 that varies according to the power mode. Since the magnitude of the input RF signal RF_{IN} is large in the high power mode, the variable gain amplifier AMP1 may have a low gain in the high power mode. Also, since the magnitude of the input RF signal RF_{IN} is small in the low power mode, the variable gain amplifier AMP1 may have a high gain in the low power mode. That is, the gain of the variable gain amplifier AMP1 may be smaller in the high power mode than in the low power mode. A method of adjusting the gain of the variable gain amplifier AMP1 according to the power mode is known to those skilled in the art, so a detailed description thereof will be omitted.

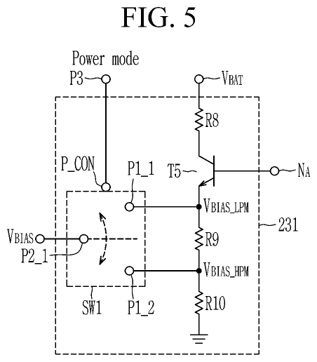

FIG. 5 is a diagram illustrating the bias voltage generating circuit 231 of FIGS. 4A and 4B according to an example.

As shown in FIG. 5, the bias voltage generating circuit 231 according to an example may include a transistor T5, a resistor R8, a resistor R9, a resistor R10, and a switch SW1.

The transistor T5 may be implemented by various types of transistors such as a heterojunction bipolar transistor (HBT), a bipolar junction transistor (BJT), and an insulated gate bipolar transistor (IGBT). In addition, although the transistor T5 is shown as an n-type in FIG. 3, it may be replaced with a p-type.

Since the base of the transistor T5 serves as a control terminal, the term ‘control terminal’ may be used. Since the collector of the transistor T5 is one terminal of the transistor, the terms ‘first terminal’ or ‘second terminal’ may be used. Also, since the emitter of the transistor T5 is one terminal of the transistor, the terms ‘second terminal’ or ‘first terminal’ may be used.

The collector of the transistor T5 may be connected to the power supply voltage V_{BAT} through the resistor R8, and the base of the transistor T5 may be connected to the node N_{A} of FIG. 3. That is, the base of the transistor T5 may be connected to the base of the transistor T3 through the resistor R4. The resistor R4 allows the base of the transistor T5 to be DC biased similarly to the base of the transistor T3 or the base of the transistor T4.

One end of the resistor R9 may be connected to the emitter of the transistor T5, and the resistor R10 may be connected between the other end of the resistor R9 and the ground. In FIG. 5, the voltage at the node where the emitter of the transistor T5 and one end of the resistor R9 are connected is denoted by ‘V_{BIAS_LPM}’. In addition, the voltage at the node where the resistor R9 and the resistor R10 are connected to each other is denoted by ‘V_{BIAS_HPM}’. The transistor T5 is set to an operating state by the voltage V_{B34} in FIG. 3, and at this time, the bias voltage V_{BIAS_LPM} is set to a higher value than the bias voltage V_{BIAS_HPM}.

As an example, when the base voltage of the transistor T5 is set to 2.4 V (i.e., when the voltage of the node N_{A} is 2.4 V), the emitter voltage of the transistor T5 may be 1.2 V. That is, the bias voltage V_{BIAS_LPM} may be 1.2 V. Here, it is assumed that the turn-on voltage of the base-emitter diode of the transistor T5 is 1.2 V. By setting the values of the resistor R9 and the resistor R10 to appropriate values, the bias voltage V_{BIAS_HPM} may be set to 0.8 V.

The switch SW1 may include two input terminals P1_1 and P1_2, one output terminal P2_1, and a control terminal P_CON. The input terminal P1_1 is connected to the emitter of the transistor T5 and receives the bias voltage V_{BIAS_LPM}. The input terminal P1_2 is connected to the other end of the resistor R9 and receives the bias voltage V_{BIAS_HPM}. The output terminal P2_1 is a terminal for outputting the bias voltage V_{BIAS} and may be connected to the resistor R5 of FIG. 4A or 4B. The control terminal P_CON is connected to the terminal P3 of FIG. 4A or FIG. 4B and receives the power mode. As an example, the switch SW1 may be a double-pole single-throw (DPST) switch.

When the power mode is the low power mode (LPM), the switch SW1 connects the input terminal P1_1 and the output terminal P2_1 to each other. At this time, the bias voltage V_{BIAS_LPM} is output as the bias voltage V_{BIAS}. That is, the bias voltage generating circuit 231 may output the bias voltage V_{BIAS_LPM} in the low power mode.

When the power mode is the high power mode (HPM), the switch SW1 connects the input terminal P1_2 and the output terminal P2_1 to each other. At this time, the bias voltage V_{BIAS_HPM} is output as the bias voltage V_{BIAS}. That is, the bias voltage generating circuit 231 may output the bias voltage V_{BIAS_HPM} in the high power mode.

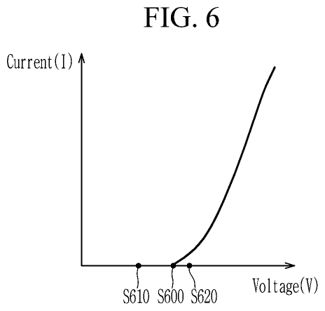

FIG. 6 is a graph showing a current (I)-voltage (V) characteristic of the diode D1 of FIGS. 4A and 4B when using the bias voltage generating circuit 231 of FIG. 5.

In FIG. 6, S600 denotes the turn-on voltage of diode D1. When the bias voltage V_{BIAS} is applied to the anode of the diode D1, the operating voltage of the diode D1 may vary.

When the bias voltage V_{BIAS_HPM} corresponding to the high power mode HPM is applied to the anode of the diode D1, the operating voltage of the diode D1 may be between the 0 V voltage and the turn-on voltage S600. As an example, the operating voltage of the diode D1 may be located at S610.

When the bias voltage V_{BIAS_LPM} corresponding to the low power mode LPM is applied to the anode of the diode D1, the operating voltage of the diode D1 may be located near the turn-on voltage S600. As an example, the operating voltage of the diode D1 may be located at S620.

In this way, the bias voltage V_{BIAS} is set differently according to the power mode, so that the position relative to the operating voltage of the diode D1 may vary. Through this, regardless of the magnitude of the input RF signal RF_{IN}, the signal detection circuits 230A and 230A′ may generate the detection signal V_{DET_A} corresponding to a predetermined level or more in the envelope signal of the input RF signal RF_{IN}.

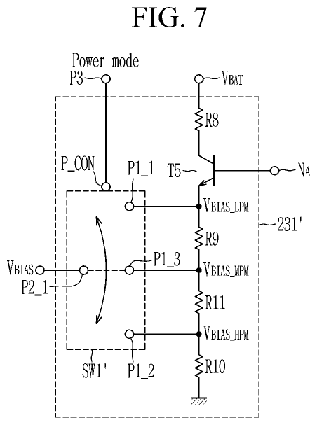

FIG. 7 is a diagram illustrating a bias voltage generating circuit 231′ according to another example.

As shown in FIG. 7, the bias voltage generating circuit 231′ according to another example may include a resistor R8, a resistor R9, a resistor R10, a resistor R11, and a switch SW1′. The bias voltage generating circuit 231′ of FIG. 7 may be similar to the bias voltage generating circuit 231 of FIG. 5 except that the resistor R11 is added and the switch SW1′ and the power modes are changed. The power modes may further include a medium power mode (MPM) in addition to the high power mode (HPM) and the low power mode (LPM).

One end of the resistor R9 may be connected to the emitter of the transistor T5, and one end of the resistor R11 may be connected to the other end of the resistor R9. The resistor R10 may be connected between the other end of the resistor R11 and the ground. In FIG. 7, the voltage at the node where the emitter of the transistor T5 and one end of the resistor R9 are connected to each other is denoted by ‘V_{BIAS_LPM}’. The voltage at the node where resistor R9 and resistor R11 are connected to each other is denoted by ‘V_{BIAS_MPM}’. The voltage at the node where the resistor R11 and R10 are connected to each other is denoted by ‘V_{BIAS_HPM}’. The transistor T5 is set to an operating state by the voltage V_{B34} in FIG. 3, and at this time, the bias voltage V_{BIAS_LPM} is set to a higher value than the bias voltage V_{BIAS_MPM}, and the bias voltage V_{BIAS_MPM} is set to a higher value than the bias voltage V_{BIAS_HPM}.

The switch SW1′ may include three input terminals P11, P1_2, and P1_3, one output terminal P2_1, and a control terminal P_CON. The input terminal P1_1 is connected to the emitter of the transistor T5 and receives the bias voltage V_{BIAS_LPM}. The input terminal P1_3 is connected to the other end of the resistor R9 and receives the bias voltage V_{BIAS_MPM}. The input terminal P1_2 is connected to the other end of the resistor R11 and receives the bias voltage V_{BIAS_HPM}. The output terminal P2_1 is a terminal for outputting the bias voltage V_{BIAS} and may be connected to the resistor R5 of FIG. 4A or FIG. 4B. The control terminal P_CON is connected to the terminal P3 of FIG. 4A or FIG. 4B and receives the power mode. As an example, the switch SW1′ may be a three-pole single-throw (3PST) switch.

When the power mode is the low power mode (LPM), the switch SW1′ connects the input terminal P1_1 and the output terminal P2_1 to each other. At this time, the bias voltage V_{BIAS_LPM} is output as the bias voltage V_{BIAS}. That is, the bias voltage generating circuit 231′ may output the bias voltage V_{BIAS_LPM} in the low power mode.

When the power mode is the medium power mode (MPM), the switch SW1′ connects the input terminal P1_3 and the output terminal P2_1 to each other. At this time, the bias voltage V_{BIAS_MPM} may be output as the bias voltage V_{BIAS}. That is, the bias voltage generating circuit 231′ may output the bias voltage V_{BIAS_MPM} in the medium power mode.

When the power mode is the high power mode, the switch SW1′ connects the input terminal P1_2 and the output terminal P2_1 to each other. At this time, the bias voltage V_{BIAS_HPM} may be output as the bias voltage V_{BIAS}. That is, the bias voltage generating circuit 231′ may output the bias voltage V_{BIAS_HPM} in the high power mode.

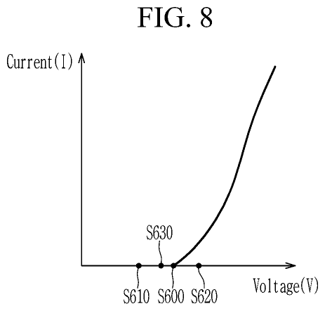

FIG. 8 is a graph showing a current (I)-voltage (V) characteristic of the diode D1 of FIGS. 4A and 4B when using the bias voltage generating circuit 231′ of FIG. 7.

The graph of FIG. 8 may be similar to the graph of FIG. 6 except that the operating voltage for the bias voltage V_{BIAS_MPM} is added.

Referring to FIG. 8, when the bias voltage V_{BIAS_MPM} corresponding to the medium power mode MPM is applied to the anode of the diode D1, the operating voltage of the diode D1 may be located between S610 and S620. As an example, the operating voltage of the diode D1 may be located at S630.

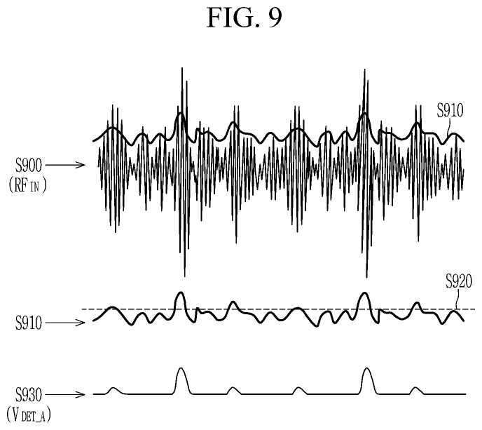

FIG. 9 is a diagram showing an example of signals in the signal detection circuits 230A and 230A′ of FIGS. 4A and 4B.

In FIG. 9, S900 denotes an example of an input RF signal RF_{IN}. S910 denotes an example of an upper envelope signal in the input RF signal RF_{IN}. In the signal detection circuits 230A and 230A′, the diode D1 and the capacitor C4 act as a rectifying circuit. That is, an upper envelope of the input RF signal RF_{IN} may be detected by the diode D1 and the capacitor C4.

In FIG. 9, a dotted line S920 denotes a value corresponding to the bias voltage V_{BIAS}. Due to the bias voltage V_{BIAS} applied to the diode D1, the signal detection circuits 230A and 230A′ may detect only values exceeding S920 in the upper envelope signal S910. Accordingly, the detection signal V_{DET_A} may have signal such as S930. In other words, the signal detection circuits 230A and 230A′ may generate a detection signal V_{DET_A} corresponding to a signal having a predetermined level or more in the input RF signal RF_{IN}. The predetermined level may correspond to the bias voltage V_{BIAS}.

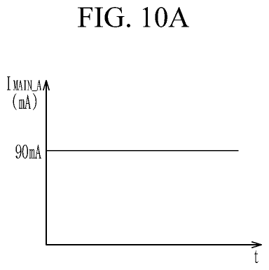

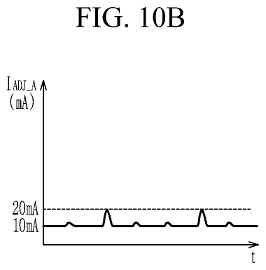

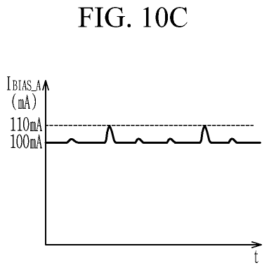

FIG. 10A is a graph conceptually illustrating the main bias current I_{MAIN_A}.

In FIG. 10A, the horizontal axis represents time (t), and the vertical axis represents the main bias current I_{MAIN_A}.

As shown in FIG. 10A, the main bias circuit 200A may generate a main bias current I_{MAIN_A} having a constant value. The main bias current I_{MAIN_A} may be set at a constant value by the base voltage V_{B3} of the transistor T3. As an example, the main bias current I_{MAIN_A} may be set to 90 mA.

FIG. 10B is a graph conceptually illustrating the adjustment bias current I_{ADJ_A}.

In FIG. 10B, the horizontal axis represents time (t), and the vertical axis represents the adjustment bias current I_{ADJ_A}.

As described above with reference to FIG. 3, the adjustment bias current I_{ADJ_A} may vary in response to the base voltage V_{B4_A} of the transistor T4. As can be seen from Equation 2 above, since the base voltage V_{B4_A} corresponds to the voltage V_{B34} having a constant value, the adjustment bias current I_{ADJ_A} may include a constant current component. As an example, a constant current component of the adjustment bias current I_{ADJ_A} may be 10 mA. As can be seen from Equation 2 above, the adjustment bias current I_{ADJ_A} may vary in response to the detection signal V_{DET_A}. When the detection signal V_{DET_A} has the same waveform as S930 of FIG. 9, the adjustment bias current I_{ADJ_A} may have a current value similar to S930. As an example, the adjustment bias current I_{ADJ_A} may vary between 10 mA and 20 mA. That is, the adjustment bias current I_{ADJ_A} may have portions increasing from 10 mA.

FIG. 10C is a graph conceptually illustrating the bias current I_{BIAS_A}.

In FIG. 10C, the horizontal axis represents time (t), and the vertical axis represents the bias current I_{BIAS_A}.

Referring to Equation 1, the bias current I_{BIAS_A} is equal to a sum of the main bias current I_{MAIN_A} and the adjustment bias current I_{ADJ_A}. Accordingly, the bias current I_{BIAS_A} may be as shown in FIG. 10C. That is, when the main bias current I_{MAIN_A} shown in FIG. 10A and the adjustment bias current I_{ADJ_A} shown in FIG. 10B are added together, the bias current I_{BIAS_A} shown in FIG. 10C may be obtained. The bias current I_{BIAS_A} may have portions increasing from 100 mA. The gain compression characteristic of the power amplifier 1000A may be improved due to the current in the increasing portions.

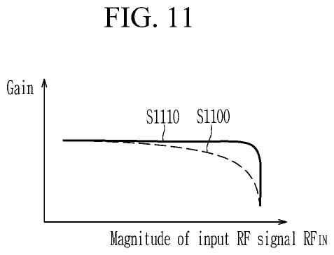

FIG. 11 is a graph showing a linearity improvement of the power amplifier 1000A according to an example.

S1100 indicates a gain compression characteristic, and S1110 indicates an improved gain compression characteristic. The power amplifier 1000A according to an example may improve linearity by detecting a signal having a predetermined level or more in the input RF signal RF_{IN}, and generating a bias current I_{BIAS_A} in response to the detected signal. More specifically, the power amplifier 1000A detects the detection signal V_{DET_A}, which is a signal corresponding to a predetermined level or more in the upper envelope signal of the input RF signal RF_{IN}, and additionally generates the adjustment bias current I_{ADJ_A} corresponding to the detection signal V_{DET_A}. Through this, linearity may be improved. That is, the gain compression characteristic of the power amplifier 1000A may be improved due to the current in the increasing portions described in FIG. 10C.

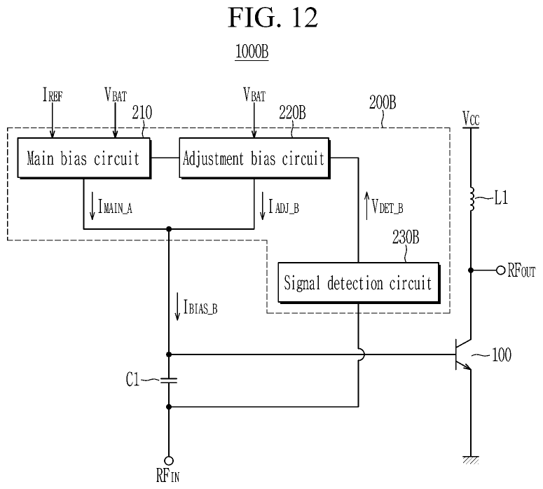

FIG. 12 illustrates a power amplifier 1000B according to another example.

As shown in FIG. 12, the power amplifier 1000B may include a power transistor 100, a bias circuit 200B, a capacitor C1, and an inductor L1.

Since the power amplifier 1000B of FIG. 12 is similar to the power amplifier 1000A of FIG. 2 except that the bias circuit 200A is replaced with the bias circuit 200B, description of overlapping parts may be omitted.

The bias circuit 200B may generate a bias current I_{BIAS_B} required by the power transistor 100 using the reference current I_{REF} and the power supply voltage V_{BAT}. The bias current I_{BIAS_B} is supplied to the input terminal (for example, the base) of the power transistor 100, and a bias level (bias point) of the power transistor 100 may be set by the bias current I_{BIAS_B}.

The power amplifier may be designed in advance to have a gain expansion characteristic as shown in FIG. 1B according to a purpose or design direction. In order to improve the linearity of the power amplifier having the gain expansion characteristic, the power amplifier 1000B detects a signal having a predetermined level or less in the input RF signal RF_{IN}, and generates a bias current I_{BIAS_B} corresponding to the detected signal.

As shown in FIG. 12, the bias circuit 200B may include a main bias circuit 210, an adjustment bias circuit 220B, and a signal detection circuit 230B. Since the bias circuit 200B of FIG. 12 is similar to the bias circuit 200A of FIG. 2, description of overlapping parts may be omitted.

The main bias circuit 210 may generate the main bias current I_{MAIN_A} using the reference current I_{REF} and the power supply voltage V_{BAT}.

The signal detection circuit 230B may receive the input RF signal RF_{IN} and generate a detection signal V_{DET_B} corresponding to a signal having a predetermined level or less in the input RF signal RF_{IN}. The detection signal V_{DET_B} is input to the adjustment bias circuit 220B. The detection signal V_{DET_B} may be a voltage signal.

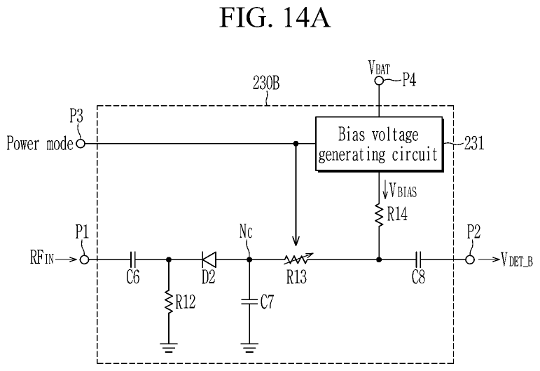

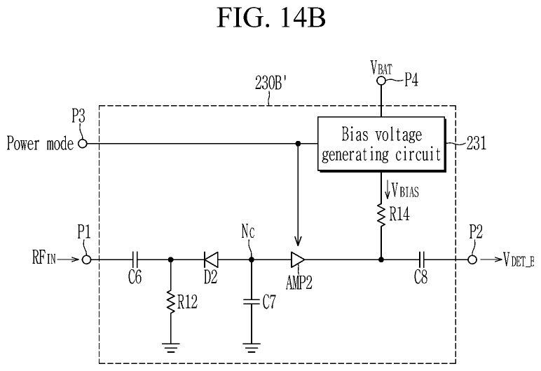

In more detail, the signal detection circuit 230B may generate the detection signal V_{DET_B}, which is a signal corresponding to a predetermined level or less in a lower envelope signal of the input RF signal RF_{IN}. That is, the signal detection circuit 230B may generate the detection signal V_{DET_B} using a lower envelope signal of the input RF signal RF_{IN}. Examples of the signal detection circuit 230B will be described with reference to FIGS. 14A and 14B below. The lower envelope signal of the input RF signal RF_{IN} may mean an envelope of an RF signal having a lower level than the average signal level of the input RF signal RF_{IN}. For example, when the average signal level of the input RF signal RF_{IN} is 0 V, the lower envelope signal may mean an envelope for an RF signal lower than 0 V in the input RF signal RF_{IN}.

The adjustment bias circuit 220B may receive the power supply voltage V_{BAT} from the outside and may receive the detection signal V_{DET_B} from the signal detection circuit 230B. The adjustment bias circuit 220B may generate the adjustment bias current I_{ADJ_B} using the power supply voltage V_{BAT} and the detection signal V_{DET_B}. The adjustment bias current I_{ADJ_B} may vary in response to the detection signal V_{DET_B}. Since the detection signal V_{DET_B} corresponds to the input RF signal RF_{IN}, the adjustment bias current I_{ADJ_B} may vary in response to the input RF signal RF_{IN}.

The bias current I_{BIAS_B}, the main bias current I_{MAIN_A}, and the adjustment bias current I_{ADJ_B} may have a relationship expressed by Equation 3 below.

I_{BIAS_B}=I_{MAIN_A}+I_{ADJ_B} (3)

Assuming that the main bias current I_{MAIN_A} is a fixed value, the bias current I_{BIAS_B} may vary according to the adjustment bias current I_{ADJ_B}. As described above, since the adjustment bias current I_{ADJ_B} varies in response to the input RF signal RF_{IN}, the bias current I_{BIAS_B} may vary in response to the input RF signal RF_{IN}. When the input RF signal RF_{IN} has a value below a predetermined level, the adjustment bias current I_{ADJ_B} may be reduced. By reducing the adjustment bias current I_{ADJ_B}, a gain expansion characteristic as shown in FIG. 1B may be improved. Improvement in the gain expansion characteristic may mean that a linearity of the power amplifier 10001B is improved.

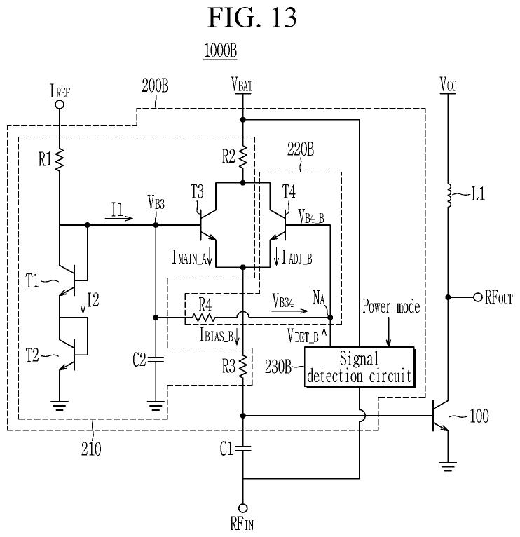

FIG. 13 is a diagram showing internal configurations of the main bias circuit 210 and the adjustment bias circuit 220B of FIG. 12.

Since the adjustment bias circuit 220B of FIG. 13 is similar to the adjustment bias circuit 220A of FIG. 3 except for some signals being changed, description of overlapping parts may be omitted.

The collector of the transistor T4 may be connected to the supply voltage V_{BAT} through the resistor R2, and the base of the transistor T4 may be connected to the base of transistor T3 through the resistor R4. The base of the transistor T4 is connected to the signal detection circuit 230B to receive the detection signal V_{DET_B}. In FIG. 13, the base voltage of the transistor T4 is denoted by ‘V_{B4_B}’, and the node where the base of the transistor T4, the signal detection circuit 230B, and the resistor R4 are connected to each other is denoted by ‘N_{A}’.

When the value of the resistor R4 is set to a high value, the base voltage V_{B3} of the transistor T3 and the base voltage V_{B4_B} of the transistor T4 may not affect each other from the viewpoint of alternating current (AC). Accordingly, from the viewpoint of an AC signal (i.e., an RF signal), the detection signal V_{DET_B} may not affect the base of the transistor T3. Because of the resistor R4, a separate power supply biasing the base of transistor T4 may not be required.

The base voltage V_{B4_B} of the transistor T4 may be equal to a sum of the voltage V_{B34} and the detection signal V_{DET_B}. That is, the base voltage V_{B4_B} of the transistor T4 may have a relationship expressed by Equation 4 below.

V_{B4_B}=V_{B34}+I_{DET_B} (4)

The detection signal V_{DET_B} may be an RF signal (i.e., AC signal), and the voltage V_{B34} may be a DC signal.

The emitter of the transistor T4 may be connected to the input terminal (i.e., base) of the power transistor 100 through the resistor R3. The emitter of the transistor T3 and the emitter of the transistor T4 may be connected to each other. One end of the resistor R3 may be connected to the emitter of the transistor T3 and the emitter of the transistor T4, and the other end of the resistor R3 may be connected to the base of the power transistor 100. The current flowing through the emitter of the transistor T4 is the adjustment bias current I_{ADJ_B} described in FIG. 12. That is, the emitter of the transistor T4 may output the adjustment bias current I_{ADJ_B}.

The adjustment bias current I_{ADJ_B} may vary in response to the base voltage V_{B4_B} of the transistor T4. In Equation 4, assuming that the voltage V_{B34} is a fixed value, the base voltage V_{B4_B} of the transistor T4 may vary in response to the detection signal V_{DET_B}. Accordingly, the adjustment bias current I_{ADJ_B} may vary in response to the detection signal V_{DET_B}. When the base voltage V_{B3} of the transistor T3 is a fixed value, the main bias current I_{MAIN_A} may be a fixed value and the voltage V_{B34} may also be a fixed value. Accordingly, when Equations 3 and 4 are considered together, the bias current I_{BIAS_B} may vary in response to the detection signal V_{DET_B}.

FIG. 14A is a diagram illustrating a signal detection circuit 230B according to an example.

As shown in FIG. 14A, the signal detection circuit 230B according to an example includes a plurality of terminals P1, P2, P3, and P4, a capacitor C6, a bias voltage generating circuit 231, a resistor R14, a variable resistor R13, a diode D2, a capacitor C7, a resistor R12, and a capacitor C8.

The input RF signal RF_{IN} is input to the terminal P1, and the detection signal V_{DET_B} is output from the terminal P2. The terminal P1 may be connected to one end of the capacitor C1, and the terminal P2 may be connected to the base (i.e., node N_{A}) of the transistor T4. In addition, the power supply voltage V_{BAT} may be input to the terminal P4.

A power mode is input to the terminal P3. As an example, the power mode may include a high power mode (HPM) and a low power mode (LPM). As another example, the power mode may include a high power mode (HPM), a medium power mode (MPM), and a low power mode (LPM).

One end of the capacitor C6 may be connected to the terminal P1. The capacitor C6 is a coupling capacitor, and may perform a function of blocking a direct current (DC) component in the input RF signal RF_{IN}.

A cathode of the diode D2 may be connected to the other end of capacitor C6. The resistor R12 may be connected between the cathode of diode D2 and a ground. The capacitor C7 may be connected between an anode of the diode D2 and the ground. In FIG. 14A, a node where the diode D2 and the capacitor C7 are connected to each other is denoted by ‘Nc’.

One end of the variable resistor R13 may be connected to the anode of the diode D2, and the resistor R14 may be connected between the other end of the variable resistor R13 and the bias voltage generating circuit 231. The resistance of the variable resistor R13 may vary according to the power mode. In order to set the magnitude of the detection signal V_{DET_B} to a similar magnitude regardless of the power mode, the variable resistor R13 may have different resistances in different power modes. That is, signal attenuation may be set differently according to the power mode by the resistance of the variable resistor R13 that varies according to the power mode. Since the magnitude of the input RF signal RF_{IN} is large in the high power mode, the variable resistor R13 may have a large resistance in the high power mode. Also, since the magnitude of the input RF signal RF_{IN} is small in the low power mode, the variable resistor R13 may have a small resistance in the low power mode. That is, the resistance of the variable resistor R13 may be set to a larger resistance in the high power mode than in the low power mode.

A capacitor C8 may be connected between the other end of the variable resistor R13 and the terminal P2. The capacitor C8 is a coupling capacitor, and may perform a function of blocking a direct current (DC) component from a signal.

The bias voltage generating circuit 231 may generate a bias voltage V_{BIAS} using the power supply voltage V_{BAT} input through the terminal P4. The bias voltage generating circuit 231 may generate the bias voltage V_{BIAS} having a different value according to the power mode input through the terminal P3. The resistor R14 is connected between the bias voltage generating circuit 231 and the other end of the variable resistor R13, and the bias voltage V_{BIAS} may be applied to the anode of the diode D2 through the resistor R14 and the variable resistor R13

By means of the bias voltage V_{BIAS}, an operating voltage of the diode D2 may be set differently according to the power mode.

FIG. 14B is a diagram illustrating a signal detection circuit 230B′ according to another example.

As shown in FIG. 14B, the signal detection circuit 230B′ according to another example includes a plurality of terminals P1, P2, P3, and P4, a capacitor C6, a bias voltage generating circuit 231, and a resistor R14, a variable gain amplifier AMP2, a diode D2, a capacitor C7, a resistor R12, and a capacitor C8. The signal detection circuit 230B′ of FIG. 14B is the same as the signal detection circuit 230B of FIG. 14A except that the variable resistor R13 is replaced with a variable gain amplifier AMP2. Accordingly, overlapping descriptions of each other may be omitted.

An input terminal of the variable gain amplifier AMP2 may be connected to the anode of the diode D2, and an output terminal of the variable gain amplifier AMP2 may be connected to one end of the capacitor C8. The capacitor C8 may be connected between the output terminal of the variable gain amplifier AMP2 and the terminal P2.

The gain of the variable gain amplifier AMP2 may vary according to the power mode. In order to set the magnitude of the detection signal V_{DET_B} to a similar magnitude regardless of the power mode, the variable gain amplifier AMP2 may have a different gains in different power modes. That is, the degree of signal amplification may be set differently according to the power mode by the gain of the variable gain amplifier AMP2 that varies according to the power mode. Since the magnitude of the input RF signal RF_{IN} is large in the high power mode, the variable gain amplifier AMP2 may have a low gain in the high power mode. Also, since the magnitude of the input RF signal RF_{IN} is small in the low power mode, the variable gain amplifier AMP2 may have a high gain in the low power mode. That is, the gain of the variable gain amplifier AMP2 may be set to a smaller gain in the high power mode than in the low power mode. A method of adjusting the gain of the variable gain amplifier AMP2 according to the power mode is known to those skilled in the art, so a detailed description thereof will be omitted.

The specific configuration of the bias voltage generating circuit 231 of FIGS. 14A and 14B may have the same configuration as the bias voltage generating circuit 231 of FIG. 5 or the bias voltage generating circuit 231′ of FIG. 7. The diode D2 of FIGS. 14A and 14B may operate similarly to the diode D1 of FIGS. 4A and 4B. Accordingly, the operating voltage of the diode D2 may be varied by the bias voltage V_{BIAS}. That is, since the bias voltage V_{BIAS} is set differently according to the power mode, the position of the bias voltage V_{BIAS} relative to the operating voltage of the diode D1 may vary as shown in FIGS. 6 and 8. Through this, regardless of the magnitude of the input RF signal RF_{IN}, the signal detection circuits 230B and 230B′ may generate the detection signal V_{DET_B} corresponding to a predetermined level or less in the envelope signal of the input RF signal RF_{IN}.

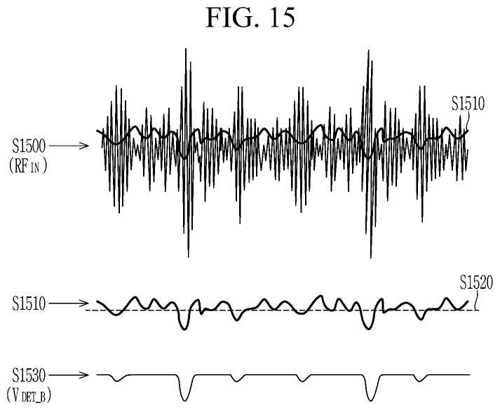

FIG. 15 is a diagram showing an example of signals in the signal detection circuits 230B and 230B′ of FIGS. 14A and 14B.

In FIG. 15, S1500 indicates an example of an input RF signal RF_{IN}. S1510 indicates an example of a lower envelope signal in the input RF signal RF_{IN}. In the signal detection circuits 230B and 230B′, the diode D2 and the capacitor C7 act as a rectifying circuit. That is, a lower envelope of the input RF signal RF_{IN} may be detected by the diode D2 and the capacitor C7.

In FIG. 15, a dotted line S1520 indicates a value corresponding to the bias voltage V_{BIAS}. Due to the bias voltage V_{BIAS} applied to the diode D2, the signal detection circuits 230B and 230B′ may detect only values corresponding to S1520 or less in the lower envelope signal S1510. Accordingly, the detection signal V_{DET_B} may have a signal such as S1530. In other words, the signal detection circuits 230B and 230B′ may generate the detection signal V_{DET_B} corresponding to a signal having a predetermined level or less in the input RF signal RF_{IN}. The predetermined level may correspond to the bias voltage V_{BIAS}.

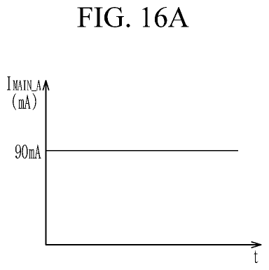

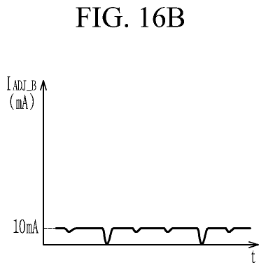

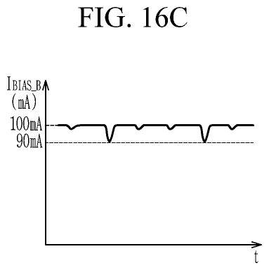

FIG. 16A is a graph conceptually illustrating the main bias current I_{MAIN_A}.

In FIG. 16A, the horizontal axis represents time (t), and the vertical axis represents the main bias current I_{MAIN_A}.

As shown in FIG. 16A, the main bias circuit 200A may generate a main bias current I_{MAIN_A} having a constant value. The main bias current I_{MAIN_A} may have a constant value set by the base voltage V_{B3} of the transistor T3. As an example, the main bias current I_{MAIN_A} may be 90 mA.

FIG. 16B is a graph conceptually illustrating the adjustment bias current I_{ADJ_B}.

In FIG. 16B, the horizontal axis represents time (t), and the vertical axis represents the adjustment bias current I_{ADJ_B}.

As described above with reference to FIG. 13, the adjustment bias current I_{ADJ_B} may vary in response to the base voltage V_{B4_B} of the transistor T4. As can be seen from Equation 4 above, since the base voltage V_{B4_B} corresponds to the voltage V_{B34} having a constant value, the adjustment bias current I_{ADJ_B} may include a constant current component. As an example, a constant current component of the adjustment bias current I_{ADJ_B} may be 10 mA. As can be seen from Equation 4 above, the adjustment bias current I_{ADJ_B} may vary in response to the detection signal V_{DET_B}. When the detection signal V_{DET_B} has the same waveform as S1530 of FIG. 15, the adjustment bias current I_{ADJ_B} may have a current value similar to S1530. As an example, the adjustment bias current I_{ADJ_B} may vary between 10 mA and 0 mA. That is, the adjustment bias current I_{ADJ_B} may have portions decreasing from 10 mA.

FIG. 16C is a graph conceptually illustrating the bias current I_{BIAS_B}.

In FIG. 16C, the horizontal axis represents time (t), and the vertical axis represents the main bias current I_{BIAS_B}.

Referring to Equation 3, the bias current I_{BIAS_B} is equal to a sum of the main bias current I_{MAIN_A} and the adjustment bias current I_{ADJ_B}. Accordingly, the bias current I_{BIAS_B} may be as shown in FIG. 16C. That is, when the main bias current I_{MAIN_A} shown in FIG. 16A and the adjustment bias current I_{ADJ_B} shown in FIG. 16B are added together, the bias current I_{BIAS_B} shown in FIG. 16C may be obtained. The bias current I_{BIAS_B} may have portions decreasing from 100 mA. The gain expansion characteristic of the power amplifier 1000B may be improved due to the current in the decreasing portions.

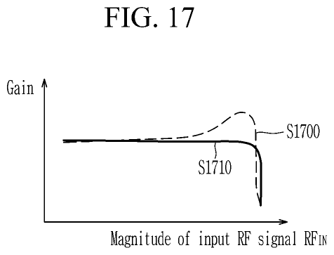

FIG. 17 is a graph showing a linearity improvement of the power amplifier 1000B according to another example.

S1700 indicates again expansion characteristic, and S1710 indicates an improved gain expansion characteristic. The power amplifier 1000B according to another example may improve a linearity of the power amplifier 1000B by detecting a signal having a predetermined level or less in the input RF signals RF_{IN} and generating a bias current I_{BIAS_B} in response to the detected signal. More specifically, the power amplifier 1000B detects the detection signal V_{DET_B}, which is a signal corresponding to a predetermined level or less in the lower envelope signal of the input RF signal RF_{IN}, and additionally generates the adjustment bias current I_{ADJ_B} corresponding to the detection signal V_{DET_B}. Through this, the linearity of the power amplifier 1000B may be improved. That is, the gain expansion characteristic of the power amplifier 1000B may be improved due to the current fin the decreasing portions shown in FIG. 16C.

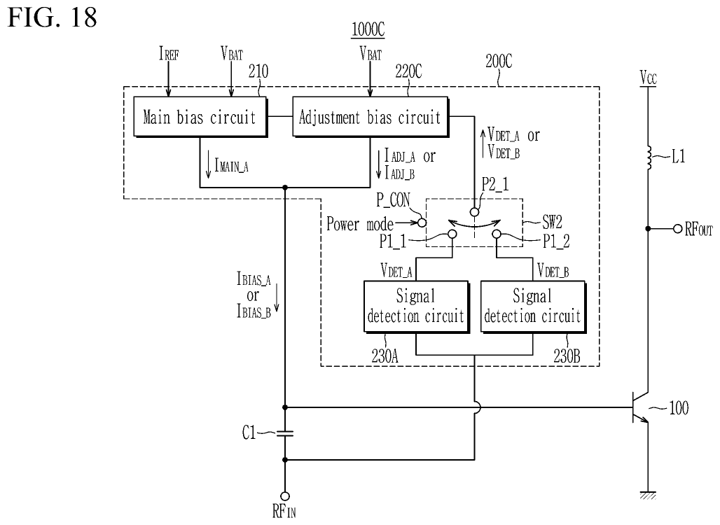

FIG. 18 is a diagram illustrating a power amplifier 1000C according to another example.

As shown in FIG. 18, a power amplifier 1000C may include a power transistor 100, a bias circuit 2000, a capacitor C1, and an inductor L1.

Since the power amplifier 1000C of FIG. 18 is similar to the power amplifier 1000A of FIG. 2 except that the bias circuit 200A is replaced with the bias circuit 2000, description of overlapping parts may be omitted.

The bias circuit 2000 may generate a bias current I_{BIAS_A} or a bias current I_{BIAS_B} required by the power transistor 100 using the reference current I_{REF} and the power supply voltage V_{BAT}. The bias circuit 2000 may generate a bias current in response to a power mode. As an example, when the power mode is a first power mode, the bias circuit 2000 may generate the bias current I_{BIAS_A}. When the power mode is a second power mode, the bias circuit 2000 may generate the bias current I_{BIAS_B}. The bias current I_{BIAS_A} or the bias current I_{BIAS_B} is supplied to the input terminal (for example, the base) of the power transistor 100, and a bias level (bias point) of the power transistor 100 may be set by the bias current I_{BIAS_A} or the bias current I_{BIAS_B}.

The power amplifier 1000C may have a gain compression characteristic or a gain expansion characteristic according to a power mode.

As an example, in the first power mode, the power amplifier 1000C may have a gain compression characteristic or a gain expansion characteristic. In order to improve the linearity of the power amplifier 1000C, the power amplifier 1000C may detect a signal having a first level or more in the input RF signal RF_{IN} and generate the bias current I_{BIAS_A} in response to the detected signal when the power amplifier 1000C has a gain compression characteristic. Alternatively, the power amplifier 1000C may detect a signal having a second level or less in the input RF signal RF_{IN} and generate the bias current I_{BIAS_B} in response to the detected signal when the power amplifier 1000C has a gain expansion characteristic.

As another example, in the second power mode, the power amplifier 1000C may have a gain compression characteristic or a gain expansion characteristic. In order to improve the linearity of the power amplifier 1000C, the power amplifier 1000C may detect a signal having a third level or more in the input RF signal RF_{IN} and generate the bias current I_{BIAS_A} in response to the detected signal when the power amplifier 1000C has a gain compression characteristic. Alternatively, the power amplifier 1000C may detect a signal having a fourth level or less in the input RF signal RF_{IN} and generate the bias current I_{BIAS_B} in response to the detected signal when the power amplifier 1000C has a gain expansion characteristic.

The first power mode may be any one of a high power mode (HPM), a medium power mode (MPM), and a low power mode (LPM), and the second power mode may be any one of a high power mode (HPM), a medium power mode (MPM), and low power mode (LPM) that is not the first power mode.

As shown in FIG. 18, the bias circuit 2000 may include a main bias circuit 210, an adjustment bias circuit 220C, a signal detection circuit 230A, a signal detection circuit 230B, and a switch SW2. The bias circuit 2000 of FIG. 18 is a combination of the bias circuit 200A of FIG. 2 and the bias circuit 200B of FIG. 12 and description of overlapping parts may be omitted.

The signal detection circuit 230A may receive the input RF signal RF_{IN} and generate a detection signal V_{DET_A} corresponding to a signal having a predetermined level or more in the input RF signal RF_{IN}. The detection signal V_{DET_A} is input to the switch SW2. The detection signal V_{DET_A} may be a voltage signal. In more detail, the signal detection circuit 230A may generate the detection signal V_{DET_A}, which is a signal corresponding to a predetermined level or more in an upper envelope signal of the input RF signal RF_{IN}. That is, the signal detection circuit 230A may generate the detection signal V_{DET_A} using an upper envelope signal of the input RF signal RF_{IN}. A specific configuration and operation of the signal detection circuit 230A may be the same as that of FIG. 4A or 4B.

The signal detection circuit 230B may receive the input RF signal RF_{IN} and generate a detection signal V_{DET_B} corresponding to a signal having a predetermined level or less in the input RF signal RF_{IN}. The detection signal V_{DET_B} is input to the switch SW2. The detection signal V_{DET_B} may be a voltage signal. More specifically, the signal detection circuit 230B may generate the detection signal V_{DET_B}, which is a signal corresponding to a predetermined level or less in a lower envelope signal of the input RF signal RF_{IN}. That is, the signal detection circuit 230B may generate the detection signal V_{DET_B} using a lower envelope signal of the input RF signal RF_{IN}. A specific configuration and operation of the signal detection circuit 230B may be the same as that of FIG. 14A or 14B.

The switch SW2 may include two input terminals P1_1 and P1_2, one output terminal P2_1, and a control terminal P_CON. The input terminal P1_1 is connected to the signal detection circuit 230A and receives the detection signal V_{DET_A}. The input terminal P1_2 is connected to the signal detection circuit 230B and receives the detection signal V_{DET_B}. The output terminal P2_1 is connected to the adjustment bias circuit 220C and outputs the detection signal V_{DET_A} or the detection signal V_{DET_B} to the adjustment bias circuit 2000. The control terminal P_CON may receive a power mode. The switch SW2 may perform a switching operation according to the power mode input to the control terminal P_CON. As an example, the switch SW2 may have a double-pole single-throw (DPST) structure.

The power amplifier 1000C may have a gain compression characteristic in the first power mode. Accordingly, in the first power mode, the switch SW2 may connect the input terminal P1_1 and the output terminal P2_1 to each other. That is, the switch SW2 outputs the detection signal V_{DET_A} in the first power mode. The detection signal V_{DET_A} generated by the signal detection circuit 230A may be applied (input) to the adjustment bias circuit 220C.

Alternatively, the power amplifier 1000C may have a gain expansion characteristic in the first power mode. Accordingly, in the first power mode, the switch SW2 may connect the input terminal P1_2 and the output terminal P2_1 to each other. That is, the switch SW2 outputs the detection signal V_{DET_B} in the first power mode. The detection signal V_{DET_B} generated by the signal detection circuit 230B may be applied (input) to the adjustment bias circuit 220C.

The power amplifier 1000C may have a gain compression characteristic in the second power mode. Accordingly, in the second power mode, the switch SW2 may connect the input terminal P1_1 and the output terminal P2_1 to each other. That is, the switch SW2 outputs the detection signal V_{DET_A} in the second power mode. The detection signal V_{DET_A} generated by the signal detection circuit 230A may be applied (input) to the adjustment bias circuit 220C.

Alternatively, the power amplifier 1000C may have a gain expansion characteristic in the second power mode. Accordingly, in the second power mode, the switch SW2 may connect the input terminal P1_2 and the output terminal P2_1 to each other. That is, the switch SW2 outputs the detection signal V_{DET_B} in the second power mode. The detection signal V_{DET_B} generated by the signal detection circuit 230B may be applied (input) to the adjustment bias circuit 220C.

The adjustment bias circuit 220C may receive the power supply voltage V_{BAT} from the outside and receive the detection signal V_{DET_A} or the detection signal V_{DET_B} from the switch SW2.

When the detection signal V_{DET_A} is input from the switch SW2, the adjustment bias circuit 220C may generate the adjustment bias current I_{ADJ_A} using the power supply voltage V_{BAT} and the detection signal V_{DET_A}. The adjustment bias current I_{ADJ_A} may vary in response to the detection signal V_{DET_A}. Since the detection signal V_{DET_A} corresponds to the input RF signal RF_{IN}, the adjustment bias current I_{ADJ_A} may vary in response to the input RF signal RF_{IN}. The bias current I_{BIAS_A}, the main bias current I_{MAIN_A}, and the adjustment bias current I_{ADJ_A} may have the relationship expressed by Equation 1 above. Referring to Equation 1, since the adjustment bias current I_{ADJ_A} varies in response to the input RF signal RF_{IN}, the bias current I_{BIAS_A} may vary in response to the input RF signal RF_{IN}. When the input RF signal RF_{IN} has a value equal to or greater than a predetermined level, the adjustment bias current I_{ADJ_A} may increase. By increasing the adjustment bias current I_{ADJ_A}, a gain compression characteristic may be improved.

When the detection signal V_{DET_B} is input from the switch SW2, the adjustment bias circuit 220C may generate the adjustment bias current I_{ADJ_B} using the power supply voltage V_{BAT} and the detection signal V_{DET_B}. The adjustment bias current I_{ADJ_B} may vary in response to the detection signal V_{DET_B}. Since the detection signal V_{DET_B} corresponds to the input RF signal RF_{IN}, the adjustment bias current I_{ADJ_B} may vary in response to the input RF signal RF_{IN}. The bias current I_{BIAS_B}, the main bias current I_{MAIN_A}, and the adjustment bias current I_{ADJ_B} may have the relationship expressed by Equation 3 above. Referring to Equation 3, since the adjustment bias current I_{ADJ_B} varies in response to the input RF signal RF_{IN}, the bias current I_{BIAS_B} may vary in response to the input RF signal RF_{IN}. When the input RF signal RF_{IN} has a value below a predetermined level, the adjustment bias current I_{ADJ_B} may be reduced. By reducing the adjustment bias current I_{ADJ_B}, a gain expansion characteristic may be improved.

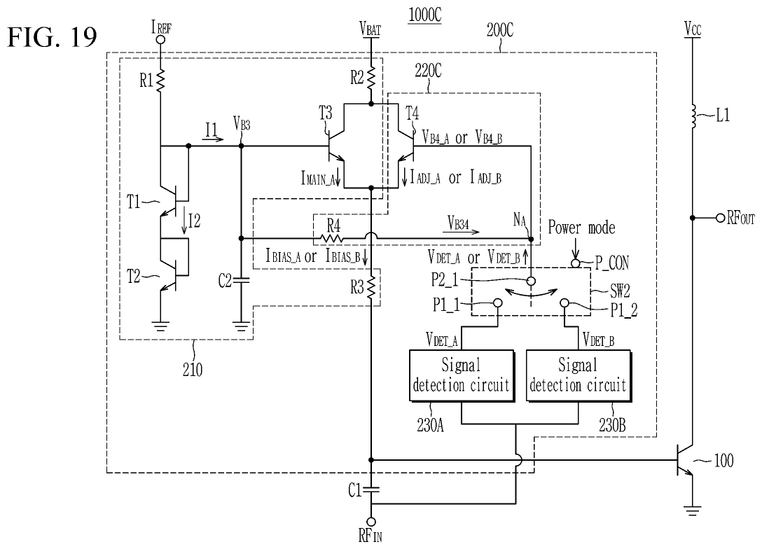

FIG. 19 is a diagram showing internal configurations of the main bias circuit 210 and the adjustment bias circuit 220C of FIG. 18.

Since the adjustment bias circuit 220C of FIG. 19 is similar to the adjustment bias circuit 220A of FIG. 3 or the adjustment bias circuit 220B of FIG. 13 except that some signals are changed, description of overlapping parts may be omitted.

The collector of the transistor T4 may be connected to the supply voltage V_{BAT} through the resistor R2, and the base of the transistor T4 may be connected to the base of the transistor T3 through the resistor R4. In addition, the base of the transistor T4 is connected to the output terminal P2_1 of the switch SW2 to receive the detection signal V_{DET_A} or the detection signal V_{DET_B}. In FIG. 19, when the detection signal V_{DET_A} is input, the base voltage of the transistor T4 is denoted by ‘V_{B4_A}’, and when the detection signal V_{DET_B} is input, the base voltage of the transistor T4 is denoted by ‘V_{B4_B}’. In addition, the node where the base of the transistor T4, the output terminal P2_1 of the switch SW2, and the resistor R4 are connected to each other is denoted by ‘N_{A}’.

When the detection signal V_{DET_A} is input from the switch SW2, the base voltage V_{B4_A} of the transistor T4 may have the relationship expressed by Equation 2 above. The adjustment bias current I_{ADJ_A} may vary in response to the base voltage V_{B4_A} of the transistor T4. Referring to Equation 2, assuming that the voltage V_{B34} is a fixed value, the base voltage V_{B4_A} of the transistor T4 may vary in response to the detection signal V_{DET_A}. Accordingly, the adjustment bias current I_{ADJ_A} may vary in response to the detection signal V_{DET_A}. As an example, the adjustment bias current I_{ADJ_A} may have the same value as that of FIG. 10B. When the base voltage V_{B3} of the transistor T3 is a fixed value, the main bias current I_{MAIN_A} may be a fixed value and the voltage V_{B34} may also be a fixed value. Accordingly, the bias current I_{BIAS_A} may vary in response to the detection signal V_{DET_A}. As an example, the bias current I_{BIAS_A} may have the same value as that of FIG. 10C, and a gain compression characteristic of the power amplifier 1000C may be improved due to the current in the increasing portions.

When the detection signal V_{DET_B} is input from the switch SW2, the base voltage V_{B4_B} of the transistor T4 may have the relationship expressed by Equation 4. The adjustment bias current I_{ADJ_B} may vary in response to the base voltage V_{B4_B} of the transistor T4. Referring to Equation 4, assuming that the voltage V_{B34} is a fixed value, the base voltage V_{B4_B} of the transistor T4 may vary in response to the detection signal V_{DET_B}. Accordingly, the adjustment bias current I_{ADJ_B} may vary in response to the detection signal V_{DET_B}. As an example, the adjustment bias current I_{ADJ_B} may have the same value as that of FIG. 16B. When the base voltage V_{B3} of the transistor T3 is a fixed value, the main bias current I_{MAIN_A} may be a fixed value and the voltage V_{B34} may also be a fixed value. Accordingly, the bias current I_{BIAS_B} may vary in response to the detection signal V_{DET_B}. As an example, the bias current I_{BIAS_B} may have a value as shown in FIG. 16C, and the gain expansion characteristic of the power amplifier 1000C may be improved due to the current in the decreasing portions.

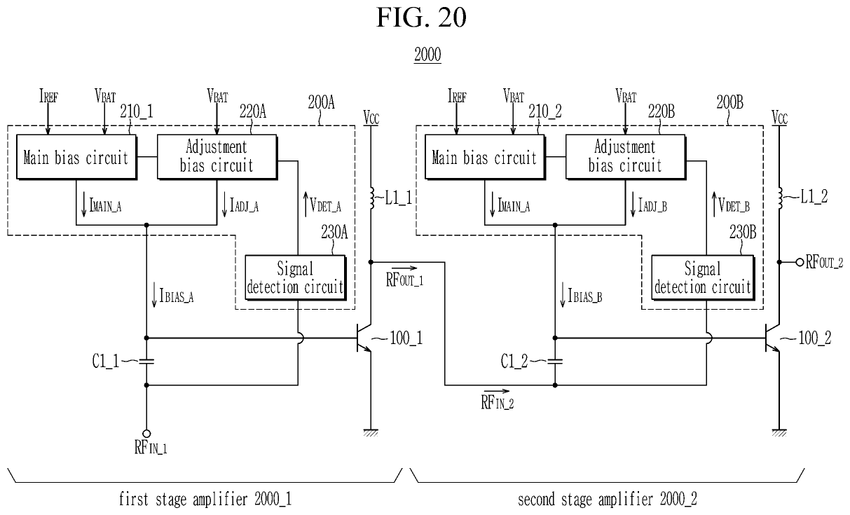

FIG. 20 is a diagram illustrating a power amplifier 2000 according to another example.

The power amplifier 2000 of FIG. 20 is a multi-stage power amplifier structure. A power transistor 100_1, the bias circuit 200A, a capacitor C1_1, and an inductor L1_1 constitute a first stage amplifier 2000_1, and the first stage amplifier 2000_1 may be similar to is the power amplifier 1000A of FIG. 2. A power transistor 1002, a bias circuit 200B, a capacitor C1_2, and an inductor L1_2 constitute a second stage amplifier 20002, and the second stage amplifier 20001 may be similar to is the power amplifier 1000B of FIG. 12. The first stage amplifier 20001 may be a driver amplifier, and the second stage amplifier 2000_2 may be a power amplifier.

The power transistor 100_1 may include an input terminal and an output terminal. The input terminal may be a base of the power transistor 100_1, and the output terminal may be a collector of the power transistor 100_1. The power transistor 100_1 may amplify a power of an input RF signal RF_{IN_1} input to the input terminal (for example, the base) and output the amplified power to the output terminal (for example, the collector). An emitter of the power transistor 100_1 may be connected to a ground. Although not shown in FIG. 20, a resistor may be additionally connected between the emitter of the power transistor 100_1 and the ground. In addition, the collector of the power transistor 100_1 may be connected to the power supply voltage V_{CC} through the inductor L1_1, and the power transistor 100_1 may be operated by the power supply voltage V_{CC}. The inductor L1_1 is connected between the power supply voltage V_{CC} and the collector of the power transistor 100_1 and may perform an RF choke function.

The power transistor 100_1 may be implemented by various types of transistors such as a heterojunction bipolar transistor (HBT), a bipolar junction transistor (BJT), and an insulated gate bipolar transistor (IGBT). Although the power transistor 100_1 is shown as an n-type transistor in FIG. 20, it may be replaced with a p-type transistor.

The capacitor C1_1 is a coupling capacitor and may be connected to the input terminal (for example, the base) of the power transistor 100_1. That is, the input RF signal RF_{IN_1} may be input to one end of the capacitor C1_1, and the other end of the capacitor C1_1 may be connected to the base of the power transistor 100_1. The capacitor C1_1 may perform a function of blocking a direct current (DC) component in the input RF signal RF_{IN_1}.

The bias circuit 200A may receive a reference current I_{REF} and a power supply voltage V_{BAT} from the outside. The bias circuit 200A may generate the bias current I_{BIAS_A} required by the power transistor 100_1 using the reference current I_{REF} and the power supply voltage V_{BAT}. The bias current I_{BIAS_A} is supplied to the input terminal (for example, the base) of the power transistor 100_1, and the bias level (bias point) of the power transistor 100_1 may be set by the bias current I_{BIAS_A}.

The first stage amplifier 2000_1 may have a gain compression characteristic. In order to improve the linearity of the first stage amplifier 20001 having the gain compression characteristic, the first stage amplifier 2000_1 detects a signal having a predetermined level or more in the input RF signal RF_{IN_1} and generates a bias current I_{BIAS_A} corresponding to the detected signal.

As shown in FIG. 20, the bias circuit 200A may include a main bias circuit 210_1, an adjustment bias circuit 220A, and a signal detection circuit 230A. The bias circuit 200A of FIG. 20 may have the same configuration and operation as the bias circuit 200A of FIG. 2. That is, the main bias circuit 210_1 may have the same configuration as the main bias circuit 210 of FIG. 3, and the adjustment bias circuit 220A of FIG. 20 may have the same configuration as the adjustment bias circuit 220A of FIG. 3.

The signal detection circuit 230A may receive the input RF signal RF_{IN_1} and generate a detection signal V_{DET_A} corresponding to a signal having a predetermined level or more in the input RF signal RF_{IN_1}. The detection signal V_{DET_A} is input to the adjustment bias circuit 220A. The detection signal V_{DET_A} may be a voltage signal. In more detail, the signal detection circuit 230A may generate the detection signal V_{DET_A}, which is a signal corresponding to a predetermined level or more in an upper envelope signal of the input RF signal RF_{IN_1}. That is, the signal detection circuit 230A may generate the detection signal V_{DET_A} using an upper envelope signal of the input RF signal RF_{IN_1}. The specific configuration and operation of the signal detection circuit 230A may be the same as that of FIG. 4A or 4B.

The adjustment bias circuit 220A may receive the power supply voltage V_{BAT} from the outside and may receive the detection signal V_{DET_A} from the signal detection circuit 230A. The adjustment bias circuit 220A may generate the adjustment bias current I_{ADJ_A} using the power supply voltage V_{BAT} and the detection signal V_{DET_A}. The adjustment bias current I_{ADJ_A} may vary in response to the detection signal V_{DET_A}. Since the detection signal V_{DET_A} corresponds to the input RF signal RF_{IN_1}, the adjustment bias current I_{ADJ_A} may vary in response to the input RF signal RF_{IN_1}. The bias current I_{BIAS_A}, the main bias current I_{MAIN_A}, and the adjustment bias current I_{ADJ_A} may have the relationship expressed by Equation 1 above. Referring to Equation 1, since the adjustment bias current I_{ADJ_A} varies in response to the input RF signal RF_{IN_1}, the bias current I_{BIAS_A} may vary in response to the input RF signal RF_{IN_1}. When the input RF signal RF_{IN_1} has a value equal to or greater than a predetermined level, the adjustment bias current I_{ADJ_A} may increase. By increasing the adjustment bias current I_{ADJ_A}, a gain compression characteristic may be improved. As an example, the adjustment bias current I_{ADJ_A} may have the same value as that of FIG. 10B and the bias current I_{BIAS_A} may have the same value as that of FIG. 10C.

The power transistor 1002 may include an input terminal and an output terminal. The input terminal may be a base of the power transistor 100_2, and the output terminal may be a collector of the power transistor. The power transistor 100_2 may amplify a power of an input RF signal RF_{IN_2} input to the input terminal (for example, the base) and output the amplified power to the output terminal (for example, the collector). An emitter of the power transistor 100_2 may be connected to a ground. Although not shown in FIG. 20, a resistor may be additionally connected between the emitter of the power transistor 100_2 and the ground. In addition, the collector of the power transistor 100_2 may be connected to the power supply voltage V_{CC} through the inductor L1_2, and the power transistor 100_2 may be operated by the power supply voltage V_{CC}. The inductor L1_2 is connected between the power supply voltage V_{CC} and the collector of the power transistor 100_2 and may perform an RF choke function.

The power transistor 100_2 may be implemented by various types of transistors such as a heterojunction bipolar transistor (HBT), a bipolar junction transistor (BJT), and an insulated gate bipolar transistor (IGBT). Although the power transistor 100_2 is shown as an n-type transistor in FIG. 20, it may be replaced with a p-type transistor.

The capacitor C₁₋₂ is a coupling capacitor and may be connected between the output terminal (for, the collector) of the power transistor 100_1 and the input terminal (for example, the base) of the power transistor 100_2. The output RF signal RF_{OUT_1} of the first stage amplifier 20001 may be input to the input terminal (base) of the power transistor 100_2 through the capacitor C1_2. That is, the output RF signal RF_{OUT_1} of the first stage amplifier 2000_1 may be the input RF signal RF_{IN_2} of the second stage amplifier 2000_2. The capacitor C₁₋₂ may perform a function of blocking a direct current (DC) component in the input RF signal RF_{IN_2}.

The bias circuit 200B may receive a reference current I_{REF} and a power supply voltage V_{BAT} from the outside. The bias circuit 200B may generate the bias current I_{BIAS_B} required by the power transistor 100_2 using the reference current I_{REF} and the power supply voltage V_{BAT}. The bias current I_{BIAS_B} is supplied to the input terminal (for example, the base) of the power transistor 100_2, and the bias level (bias point) of the power transistor 100_2 may be set by the bias current I_{BIAS_B}.

The second stage amplifier 2000_2 may have a gain expansion characteristic. In order to improve the linearity of the second stage amplifier 20002 having the gain expansion characteristic, the second stage amplifier 2000_2 detects a signal having a predetermined level or less in the input RF signal RF_{IN_2} and generates the bias current I_{BIAS_B} corresponding to the detected signal.

As shown in FIG. 20, the bias circuit 200B may include a main bias circuit 2102, an adjustment bias circuit 220B, and a signal detection circuit 230B. The bias circuit 200B of FIG. 20 may have the same configuration and operation as the bias circuit 200B of FIG. 12. That is, the main bias circuit 210_2 may have the same configuration as the main bias circuit 210 of FIG. 13, and the adjustment bias circuit 220B of FIG. 20 may have the same configuration as the adjustment bias circuit 220B of FIG. 13.

The signal detection circuit 230B may receive the input RF signal RF_{IN_2} and generate a detection signal V_{DET_B} corresponding to a signal having a predetermined level or less in the input RF signal RF_{IN_2}. The detection signal V_{DET_B} is input to the adjustment bias circuit 220B. The detection signal V_{DET_B} may be a voltage signal. In more detail, the signal detection circuit 230B may generate the detection signal V_{DET_B}, which is a signal corresponding to a predetermined level or less in a lower envelope signal of the input RF signal RF_{IN_2}. That is, the signal detection circuit 230B may generate the detection signal V_{DET_B} using a lower envelope signal of the input RF signal RF_{IN_2}. The specific configuration and operation of the signal detection circuit 230B may be the same as that of FIG. 14A or 14B.

The adjustment bias circuit 220B may receive the power supply voltage V_{BAT} from the outside and may receive the detection signal V_{DET_B} from the signal detection circuit 230B. The adjustment bias circuit 220B may generate the adjustment bias current I_{ADJ_B} using the power supply voltage V_{BAT} and the detection signal V_{DET_B}. The adjustment bias current I_{ADJ_B} may vary in response to the detection signal V_{DET_B}. Since the detection signal V_{DET_B} corresponds to the input RF signal RF_{IN_2}, the adjustment bias current I_{ADJ_B} may vary in response to the input RF signal RF_{IN_2}. The bias current I_{BIAS_B}, the main bias current I_{MAIN_A}, and the adjustment bias current I_{ADJ_B} may have the relationship expressed by Equation 3 above. Referring to Equation 3, since the adjustment bias current I_{ADJ_B} varies in response to the input RF signal RF_{IN_2}, the bias current I_{BIAS_B} may vary in response to the input RF signal RF_{IN_2}. When the input RF signal RF_{IN_2} has a value equal to or less than a predetermined level, the adjustment bias current I_{ADJ_B} may decrease. By reducing the adjustment bias current I_{ADJ_B}, a gain expansion characteristic may be improved. As an example, the adjustment bias current I_{ADJ_B} may have the same value as that of FIG. 16B and the bias current I_{BIAS_B} may have the same value as that of FIG. 16C.

In FIG. 20, the case where the first stage amplifier 2000_1 has a gain compression characteristic and the second stage amplifier 2000_2 has a gain expansion characteristic has been described, but the first stage amplifier 2000_1 may have a gain expansion characteristic and the second stage amplifier 2000_2 may have a gain compression characteristic. In this case, the bias circuit 200A and the bias circuit 200B may be interchanged with each other. That is, the first-stage amplifier 2000_1 may include the bias circuit 200B instead of the bias circuit 200A, and through this, the gain expansion characteristic may be improved. In addition, the second stage amplifier 2000_2 may include the bias circuit 200A instead of the bias circuit 200B, and through this, the gain compression characteristic may be improved.

As described above, according to at least one aspect, a linearity of a power amplifier may be improved by adjusting the bias current in response to the input RF signal.

Also, according to at least one aspect, a gain compression characteristic of the power amplifier may be improved by generating a bias current by detecting a signal having a predetermined level or more in the input RF signal.

Also, according to at least one aspect, a gain expansion characteristic of the power amplifier may be improved by generating a bias current by detecting a signal having a predetermined level or less in the input RF signal.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power amplifier comprising:
a power transistor configured to amplify an input radio-frequency (RF) signal; and
a bias circuit configured to provide a bias current to the power transistor,
wherein the bias circuit is further configured to:
in a first power mode, detect a first signal corresponding to a first level or more in the input RF signal and generate the bias current as a bias current corresponding to the first signal, or detect a second signal corresponding to a second level or less in the input RF signal and generate the bias current as a bias current corresponding to the second signal, and
in a second power mode, detect a third signal corresponding to a third level or more in the input RF signal and generate the bias current as a bias current corresponding to the third signal, or detect a fourth signal corresponding to a fourth level or less in the input RF signal and generate the bias current as a bias current corresponding to the fourth signal.

2. The power amplifier of claim 1, wherein in the first power mode, the bias current increases in response to the first signal or the bias current decreases in response to the second signal, and
in the second power mode, the bias current increases in response to the third signal or the bias current decreases in response to the fourth signal.

3. The power amplifier of claim 2, wherein the first signal corresponds to a signal having the first level or more in an upper envelope signal of the input RF signal,
the second signal corresponds to a signal having the second level or less in a lower envelope signal of the input RF signal,
the third signal corresponds to a signal having the third level or more in the upper envelope signal of the input RF signal, and
the fourth signal corresponds to a signal having the fourth level or less in the lower envelope signal of the input RF signal.

4. The power amplifier of claim 1, wherein the bias circuit comprises:
a main bias circuit configured to generate a main bias current using a reference current;
a first signal detection circuit configured to generate the first signal or the third signal using the input RF signal;
a second signal detection circuit configured to generate the second signal or the fourth signal using the input RF signal; and
an adjustment bias circuit configured to generate an adjustment bias current corresponding to the first signal, or the second signal, or the third signal, or the fourth signal, and
the bias current is equal to a sum of the main bias current and the adjustment bias current.

5. The power amplifier of claim 4, wherein the main bias circuit comprises a first transistor configured to provide the main bias current to the power transistor, and
the adjustment bias circuit comprises a second transistor configured to provide the adjustment bias current to the power transistor.

6. The power amplifier of claim 5, wherein the first transistor comprises a control terminal to which a current corresponding to the reference current is input, and a first terminal from which the main bias current is output,
the second transistor comprises a control terminal to which the first signal, or the second signal, or the third signal, or the fourth signal is input, and a first terminal from which the adjustment bias current is output,
the first terminal of the first transistor and the first terminal of the second transistor are connected to each other, and
the adjustment bias circuit further comprises a first resistor connected between the control terminal of the first transistor and the control terminal of the second transistor.

7. The power amplifier of claim 4, wherein the first power mode is any one of a high power mode, a medium power mode, and a low power mode, and
the second power mode is any one of the high power mode, the medium power mode, and the low power mode that is not the first power mode.

8. The power amplifier of claim 4, wherein the bias circuit further comprises a switch configured to select any one of the first to fourth signals according to the first and second power modes and output the selected any one signal to the adjustment bias circuit.

9. The power amplifier of claim 4, wherein the first signal detection circuit is further configured to:
in the first power mode, generate the first signal as a first signal corresponding to a signal having the first level or more in an upper envelope signal of the input RF signal, and
in the second power mode, generate the third signal as a third signal corresponding to a signal having the third level or more in an upper envelope signal of the input RF signal.

10. The power amplifier of claim 4, wherein the second signal detection circuit is further configured to:
in the first power mode, generate the second signal as a second signal corresponding to a signal having the second level or less in a lower envelope signal of the input RF signal, and
in the second power mode, generate the fourth signal as a fourth signal corresponding to a signal having the fourth level or less in a lower envelope signal of the input RF signal.

11. The power amplifier of claim 1, wherein the first level is the same as the third level, and
the second level is the same as the fourth level.

12. A power amplifier comprising:
a power transistor configured to amplify an input radio-frequency (RF) signal; and
a bias circuit configured to provide a bias current to the power transistor,
wherein the bias circuit is further configured to detect a first signal corresponding to a first level or more in the input RF signal and generate the bias current as a bias current corresponding to the first signal.

13. The power amplifier of claim 12, wherein the first signal is a signal corresponding to the first level or more in a upper envelope signal of the input RF signal.

14. The power amplifier of claim 12, wherein the bias current increases in response to the first signal.

15. The power amplifier of claim 12, wherein the bias circuit comprises:
a main bias circuit configured to generate a main bias current using a reference current;
a signal detection circuit configured to detect the first signal using the input RF signal; and
an adjustment bias circuit configured to generate an adjustment bias current corresponding to the first signal,
wherein the bias current is equal to a sum of the main bias current and the adjustment bias current.

16. The power amplifier of claim 15, wherein the main bias circuit comprises a first transistor configured to provide the main bias current to the power transistor, and
the adjustment bias circuit comprises a second transistor configured to provide the adjustment bias current to the power transistor.

17. The power amplifier of claim 16, wherein the first transistor comprises a control terminal to which a current corresponding to the reference current is input, and a first terminal from which the main bias current is output,
the second transistor comprises a control terminal to which the first signal is input, and a first terminal from which the adjustment bias current is output,
the first terminal of the first transistor and the first terminal of the second transistor are connected to each other, and
the adjustment bias circuit further comprises a first resistor connected between the control terminal of the first transistor and the control terminal of the second transistor.

18. The power amplifier of claim 15, wherein the signal detection circuit comprises:
a first terminal to which the input RF signal is input;
a diode having an anode connected to the first terminal;
a bias voltage generating circuit configured to provide a bias voltage to the anode of the diode;
a capacitor connected between a cathode of the diode and a ground; and
a second terminal configured to output the first signal.

19. The power amplifier of claim 18, wherein the bias voltage generating circuit is further configured to generate the bias voltage as a bias voltage having a value that varies according to a power mode.

20. The power amplifier of claim 19, wherein the signal detection circuit further comprises:
a first resistor connected between the bias voltage generating circuit and the anode of the diode;
a variable resistor having one end connected to the cathode of the diode and a resistance that varies according to the power mode; and
a second resistor connected between another end of the variable resistor and the ground.

21. The power amplifier of claim 20, wherein the variable resistor has a first resistance in a first power mode and a second resistance lower than the first resistance in a second power mode, and
the first power mode is a power mode requiring a higher power than the second power mode.

22. The power amplifier of claim 19, wherein the bias voltage generating circuit comprises:
a transistor comprising a control terminal, a first terminal, and a second terminal, wherein the first terminal is configured to be connected to a power supply voltage;
a first resistor having one end connected to the second terminal of the transistor;
a second resistor connected between another end of the first resistor and the ground; and
a switch configured to output the bias voltage by selecting a voltage at the second terminal of the transistor or a voltage at another end of the first resistor according to the power mode.

23. The power amplifier of claim 19, wherein the bias voltage has a first voltage value in a first power mode and a second voltage value higher than the first voltage value in a second power mode, and
the first power mode is a power mode requiring a higher power than the second power mode.

24. The power amplifier of claim 19, wherein the signal detection circuit further comprises:
a first resistor connected between the bias voltage generating circuit and the anode of the diode;
a variable gain amplifier having an input terminal connected to the cathode of the diode and having a gain that varies according to the power mode; and
a second resistor connected between an output terminal of the variable gain amplifier and the ground.

25. The power amplifier of claim 24, wherein the gain has a first gain value in a first power mode and a second gain higher than the first gain in a second power mode, and
the first power mode is a power mode requiring a higher power than the second power mode.

26. A power amplifier comprising:
a power transistor configured to amplify an input radio-frequency (RF) signal; and
a bias circuit configured to provide a bias current to the power transistor,
wherein the bias circuit is further configured to detect a first signal corresponding to a first level or less in the input RF signal and generate the bias current as a bias current corresponding to the first signal.

27. The power amplifier of claim 26, wherein the first signal is a signal corresponding to the first level or less in a lower envelope signal of the input RF signal.

28. The power amplifier of claim 26, wherein the bias current decreases in response to the first signal.

29. The power amplifier of claim 26, wherein the bias circuit comprises:
a main bias circuit configured to generate a main bias current using a reference current;
a signal detection circuit configured to detect the first signal using the input RF signal; and
an adjustment bias circuit configured to generate an adjustment bias current corresponding to the first signal,
wherein the bias current is equal to a sum of the main bias current and the adjustment bias current.

30. The power amplifier of claim 29, wherein the signal detection circuit comprises:
a first terminal to which the input RF signal is input;
a diode having a cathode connected to the first terminal;
a bias voltage generating circuit configured to provide a bias voltage to an anode of the diode;
a capacitor connected between the anode of the diode and a ground; and
a second terminal configured to output the first signal.

31. The power amplifier of claim 30, wherein the bias voltage generating circuit is further configured to generate the bias voltage as a bias voltage having a value that varies according to a power mode.

32. The power amplifier of claim 31, wherein the signal detection circuit further comprises:
a first resistor connected between the cathode of the diode and the ground;
a variable resistor having one end connected to the anode of the diode and having a resistance that varies according to the power mode; and
a second resistor connected between the bias voltage generating circuit and another end of the variable resistor.

33. The power amplifier of claim 32, wherein the variable resistor has a first resistance in a first power mode and a second resistance lower than the first resistance in a second power mode, and
the first power mode is a power mode requiring a higher power than the second power mode.

34. The power amplifier of claim 31, wherein the signal detection circuit further comprises:
a first resistor connected between the cathode of the diode and the ground;
a variable gain amplifier having an input terminal connected to the anode of the diode and having a gain that varies according to the power mode; and
a second resistor connected between the bias voltage generating circuit and an output terminal of the variable gain amplifier.

35. The power amplifier of claim 34, wherein the gain is a first gain in a first power mode and a second gain higher than the first gain in a second power mode, and
the first power mode is a power mode requiring a higher power than the second power mode.

36. The power amplifier of claim 31, wherein the bias voltage has a first voltage value in a first power mode and a second voltage value higher than the first voltage value in a second power mode, and
the first power mode is a power mode requiring a higher power than the second power mode.

37. A power amplifier comprising:
a first power transistor configured to amplify a first input radio-frequency (RF) signal;
a first bias circuit configured to provide a first bias current to the first power transistor;
a second power transistor configured to amplify a second input RF signal; and
a second bias circuit configured to provide a second bias current to the second power transistor,
wherein the first bias circuit is further configured to detect a first signal corresponding to a first level or more in the first input RF signal and generate the first bias current as a first bias current corresponding to the first signal, and
the second bias circuit is further configured to detect a second signal corresponding to a second level or less in the second input RF signal and generate the second bias current as a second bias current corresponding to the second signal.

38. The power amplifier of claim 37, wherein the second input RF signal is an RF signal amplified and output by the first power transistor.

39. The power amplifier of claim 37, wherein the first bias current increases in response to the first signal, and
the second bias current decreases in response to the second signal.

40. The power amplifier of claim 39, wherein the first signal is a first signal corresponding to the first level or more in a upper envelope signal of the first input RF signal, and
the second signal is a second signal corresponding to the second level or less in a lower envelope signal of the second input RF signal.

41. The power amplifier of claim 37, wherein the first bias circuit comprises:
a first main bias circuit configured to generate a first main bias current using a first reference current;
a first signal detection circuit configured to generate the first signal using the first input RF signal; and
a first adjustment bias circuit configured to generate a first adjustment bias current corresponding to the first signal, and
the second bias circuit comprises:
a second main bias circuit configured to generate a second main bias current using the second reference current;
a second signal detection circuit configured to generate the second signal using the second input RF signal; and
a second adjustment bias circuit configured to generate a second adjustment bias current corresponding to the second signal,
wherein the first bias current is equal to a sum of the first main bias current and the first adjustment bias current, and
the second bias current is equal to a sum of the second main bias current and the second adjustment bias current.

42. The power amplifier of claim 41, wherein the first main bias circuit comprises a first transistor configured to provide the first main bias current to the first power transistor,
the first adjustment bias circuit comprises a second transistor configured to provide the first adjustment bias current to the first power transistor,
the second main bias circuit comprises a third transistor configured to provide the second main bias current to the second power transistor, and
the second adjustment bias circuit comprises a fourth transistor configured to provide the second adjustment bias current to the second power transistor.

43. The power amplifier of claim 41, wherein the first signal detection circuit is further configured to generate the first signal as a first signal corresponding to a signal having the first level or more in an upper envelope signal of the first input RF signal, and
the second signal detection circuit is further configured to generate the second signal as a second signal corresponding to a signal having the second level or less in a lower envelope signal of the second input RF signal.

44. The power amplifier of claim 37, wherein the first power transistor and the first bias circuit constitute a first stage amplifier, and
the second power transistor and the second bias circuit constitute a second stage amplifier.
